(19) United States
(12) Patent Application Publication
(10) Pub. No.: US 2026/0085404 A1
(43) Pub. Date: Mar. 26, 2026

(54) PRECURSOR COMPOSITION FOR THIN FILM DEPOSITION, METHOD FOR MANUFACTURING THIN FILM AND THIN FILM MANUFACTURED USING THE SAME, AND ELECTRONIC DEVICE COMPRISING THIN FILM

(71) Applicants: Samsung Display Co., Ltd., Yongin-Si (KR); JI-tech Co.,ltd, Gunsan-si (KR)

(72) Inventors: YUNG BIN CHUNG, Yongin-si (KR); WOO-SEOK JEON, Yongin-si (KR); SUKHUN HAM, Gunsan-si (KR); JONG MU NA, Gunsan-si (KR); JOO YOUNG LEE, Jeonju-si (KR); SECHANG LIM, Gunsan-si (KR); JUN HYUNG LIM, Yongin-si (KR)

(21) Appl. No.: 19/078,282

(22) Filed: Mar. 13, 2025

(30) Foreign Application Priority Data
Sep. 23, 2024 (KR) 10-2024-0128286

(51) Int. Cl. C23C 16/18; C23C 16/44; C23C 16/455; C23C 16/56; H01L 21/02; H10D 62/80

(52) U.S. Cl. CPC C23C 16/18; C23C 16/4408; C23C 16/45553; C23C 16/56; H10D 62/875; H10P 14/3434

(57) ABSTRACT

The present disclosure provides a precursor composition for deposition of a thin film including liquid indium precursor, liquid gallium precursor and liquid zinc precursor, a manufacturing method of the thin film by using the precursor composition, the thin film manufactured by using the precursor composition and an electronic device including the thin film.

### CROSS-REFERENCE TO RELATED APPLICATIONS

This application claims priority to and benefits of Korean Patent Application No. 10-2024-0128286 under 35 U.S.C § 119, filed on Sep. 23, 2024, in the Korean Intellectual Property Office, the contents of which are incorporated herein in its entirety by reference.

### BACKGROUND

### 1. Technical Field

The present disclosure relates to a precursor composition for deposition of a thin film, a manufacturing method of a thin film and a thin film manufactured by using the same and an electronic device including the thin film.

### 2. Description of the Related Art

A material added with various types of a metal atom, such as indium and zinc, is used for an oxide semiconductor, and a thin film of an oxide semiconductor is manufactured through a process, such as sputtering, atomic layer deposition (ALD), pulsed laser deposition (PLD), and chemical vapor deposition (CVD).

Recently, a crystalline oxide semiconductor referred as Indium Gallium Zinc Oxide IGZO, a composite oxide film of indium, gallium, and zinc, is being used in a thin film transistor (TFT). A thin film transistor including an IGZO composite oxide film may be applicable to a large-area display with high resolution.

### SUMMARY

An object of the present disclosure is to provide a precursor composition for deposition of a thin film, a manufacturing method of the thin film and the thin film manufactured by using the same, and an electronic device including the thin film.

An object of the present disclosure is not limited to what is described above, and other undescribed objects should be clearly understood from the Detailed Description by a person ordinarily skilled in the art.

According to an aspect of the present disclosure, a precursor composition for deposition of a thin film may include liquid indium precursor, liquid gallium precursor, and liquid zinc precursor.

According to an embodiment of the present disclosure, a molar ratio of indium:gallium:zinc in the precursor composition for deposition of the thin film may be 0.1 to 10:0.1 to 10:0.1 to 10.

According to an embodiment of the present disclosure, the liquid indium precursor may be one or more species selected from triethylindium, tripropylindium, and tri (tert-butyl) indium.

According to an embodiment of the present disclosure, the precursor composition for deposition of the thin film may not include a solvent.

According to an embodiment of the present disclosure, all of the liquid indium precursor, the liquid gallium precursor, and the liquid zinc precursor may be an alkyl-based precursor.

According to another aspect of the present disclosure, a manufacturing method of a thin film is provided, the method may include i) preparing a precursor composition for deposition of the thin film by mixing liquid indium precursor, liquid gallium precursor, and liquid zinc precursor and ii) forming the thin film on a substrate by using the precursor composition.

According to an embodiment of the present disclosure, indium, gallium, and zinc in the precursor composition for deposition of the thin film may be mixed in a molar ratio of 0.1 to 10:0.1 to 10:0.1 to 10.

According to an embodiment of the present disclosure, the liquid indium precursor may be one or more species selected from triethylindium, tripropylindium, and tri (tert-butyl) indium.

According to an embodiment of the present disclosure, the precursor composition for deposition of the thin film may not involve use of a solvent.

According to an embodiment of the present disclosure, the forming of the thin film may be performed through atomic layer deposition (ALD) or chemical vapor deposition (CVD) by using the precursor composition for deposition of the thin film.

According to an embodiment of the present disclosure, a temperature forming the thin film may be between 100° C. to 300° C.

According to an embodiment of the present disclosure, the manufacturing method may further include vaporizing the precursor composition using a vaporizer before forming the thin film.

According to an embodiment of the present disclosure, the manufacturing method may further include first purging a chamber using inert gas after forming the thin film.

According to an embodiment of the present disclosure, the manufacturing method may further include oxidizing the thin film by using reactive gas after the first purging.

According to an embodiment of the present disclosure, a flow rate of the reactive gas may be 50 sccm to 500 sccm, and the supply time of the reactive gas may be 0.1 seconds to 60 seconds.

According to an embodiment of the present disclosure, the manufacturing method may further include second purging the chamber using inert gas after the oxidizing the thin film.

According to another aspect of the present disclosure, a thin film formed on a substrate by using a precursor composition including liquid indium precursor, liquid gallium precursor, and liquid zinc precursor is provided. The thin film is a single amorphous layer including indium, gallium, and zinc.

According to an embodiment of the present disclosure, the thin film may be formed through atomic layer deposition (ALD) or chemical vapor deposition (CVD) by using the precursor composition.

According to an embodiment of the present disclosure, a content ratio of indium in the thin film may be 10 wt % or more.

According to an embodiment of the present disclosure, the thin film may have a refractive index of 1.5 to 2.5 with light of a 630 nm wavelength.

According to an aspect of the present disclosure, an electronic device may include a thin film formed by using a precursor composition comprising liquid indium precursor, liquid gallium precursor, and liquid zinc precursor. The thin film is a single amorphous layer including indium, gallium and zinc.

According to an embodiment of the present disclosure, the electronic device may be one of a plane panel display, a curved display, a television, a billboard, a computer monitor, a medical monitor, a head mounted display (HMD), an indoor or outdoor lighting or light for signal, a wearable device, a foldable device, a rollable device, a bendable device, a flexible device, a curved device, an electronic notebook, an electronic book, a portable multimedia player (PMP), a personal digital assistant (PDA), a laser printer, a telephone, a cellphone, a tablet, a portable terminal, a notebook, a laptop, a digital camera, a viewfinder, a camcorder, a 3D display, a virtual reality or augmented reality display, a video wall containing multiple displays tiled together, a vehicle, an outdoor display device, a theater or stadium screen, and a signboard.

According to an embodiment of the present disclosure, it becomes possible to provide a manufacturing method of a thin film with a simplified manufacturing process and shortened manufacturing process time by using a mixed liquid precursor composition for deposition of a thin film, a thin film with an advanced physical property manufactured by using a mixed liquid precursor composition for deposition of a thin film, and an electronic device including the thin film.

However, an effect of the present disclosure is not limited to the above effects but can be expanded within a scope not departing from an idea and scope of the present disclosure.

### BRIEF DESCRIPTION OF THE DRAWINGS

These and/or other features will become apparent and more readily appreciated from the following description of the embodiments, taken in conjunction with the accompanying drawings in which:

FIG. 1A is a conceptual illustration of a device for manufacturing a thin film by providing a conventional source for deposition of an IGZO thin film, and FIG. 1B is a schematic illustration of a separate process for manufacturing a thin film by sequentially providing sources of three types for deposition of an IGZO thin film by using the device;

FIG. 2A is a conceptual illustration of a device for manufacturing a thin film by providing a liquid three-component based, mixed precursor composition for deposition of an IGZO thin film according to an embodiment of the present disclosure through liquid delivery system (LDS) and simultaneously providing gaseous indium precursor, gallium precursor, and zinc precursor, which are vaporized by a vaporizer, on a substrate, and FIG. 2B is a schematic illustration of a separate process for manufacturing a thin film by providing a three-component based, mixed precursor composition for deposition of an IGZO thin film by using the device;

FIG. 3 is an illustration of a gas flow in each process for forming an IGZO thin film through atomic layer deposition by using liquid delivery system (LDS) of the device shown in FIG. 2A according to an embodiment of the present disclosure;

FIG. 4 is a conceptual illustration of a device for manufacturing a thin film by providing a three-component based, mixed precursor composition for deposition of an IGZO thin film according to an embodiment of the present disclosure through by-pass and sequentially providing vaporized gaseous indium precursor, gallium precursor and zinc precursor on a substrate according to a vapor pressure;

FIG. 5A is a schematic cross-sectional view of a thin film transistor including an IGZO thin film formed by using a three-component based, mixed precursor composition for deposition of an IGZO thin film according to an embodiment of the present disclosure, and FIG. 5B is a schematic front view of the thin film transistor;

FIGS. 6 and 7 are illustrations of an electronic device applied with a display device including a thin film according to an embodiment of the present disclosure;

FIGS. 8A through 8C are graphs showing a result of a measured Nuclear Magnetic Resonance NMR of each source after synthesizing sources of a gallium precursor, an indium precursor, and a zinc precursor for manufacturing a three-component based, mixed precursor composition for deposition of an IGZO thin film according to an embodiment of the present disclosure;

FIGS. 9A, 9B and 9C are graphs showing a result of a measured NMR of a composition after manufacturing a three-component based, mixed precursor composition for deposition of an IGZO thin film according to an embodiment of the present disclosure;

FIGS. 10A, 10B and 10C are illustrations showing an NMR analysis result of triethylindium, which is an indium precursor according to an embodiment of the present disclosure;

FIG. 11 is an illustration showing a mass spectrometry (GC/MS) result of a three-component based, mixed precursor composition of deposition of an IGZO thin film according to an embodiment of the present disclosure;

FIGS. 12A, 12B, 12C, 12D, 12E and 12F are illustrations showing a mass spectrometry (GC/MS) result of each component in a three-component based, mixed precursor composition for deposition of an IGZO thin film according to an embodiment of the present disclosure;

FIG. 13 is an illustration of an analysis result by using thermogravimetric analysis (TGA) for measurement of thermal stability and a decomposition temperature of liquid indium precursor, liquid gallium precursor, and liquid zinc precursor in a three-component based, mixed precursor composition for an IGZO thin film according to an embodiment of the present disclosure;

FIG. 14 is a Scanning Electron Microscopy SEM image obtained by photographing a cross-sectional view of an IGZO thin film formed by atomic layer deposition according to an embodiment of the present disclosure;

FIG. 15 is a graph showing an X-ray Diffraction XRD result of an IGZO thin film formed by atomic layer deposition according to an embodiment of the present disclosure;

FIG. 16A is a graph showing measurement result of measuring growth per cycle (GPC) and a thickness by using ellipsometer according to the number of deposition cycles of an IGZO thin film formed by atomic layer deposition according to an embodiment of the present disclosure, and FIG. 16B is a graph showing growth per cycle (GPC) according to a deposition temperature of an IGZO thin film formed by atomic layer deposition according to an embodiment of the present disclosure;

FIGS. 17A and 17B are illustrations of a composition ratio for a component of a thin film by using an X-ray Photoelectron Spectroscopy XPS of a thin film formed through atomic layer deposition by using a three-component based, mixed precursor composition for an IGZO thin film according to an embodiment of the present disclosure;

Each of FIGS. 18A and 18B is a surface mapping and a sectional mapping of components obtained by Scanning Electron Microscopy/Energy-Dispersive X-ray Spectrometry SEM_EDS analysis of a thin film formed through atomic layer deposition according to an embodiment of the present disclosure;

Each of FIGS. 19A and 19B is an illustration of a refractive index and an absorption ratio of a thin film formed through atomic layer deposition according to an embodiment of the present disclosure;

FIG. 20A is a graph showing an O1s peak of a thin film obtained by using a photoelectron spectroscopy of a thin film formed through atomic layer deposition according to an embodiment of the present disclosure, and FIG. 20B is a graph showing an O1s peak deconvoluted to three peaks;

FIGS. 21 and 22 are Atomic Force Microscopy AFM illustrations showing growth behavior and root-mean-square surface roughness of an IGZO thin film according to an embodiment of the present disclosure through a three-dimensional granular morphology and a two-dimensional morphology; and

FIG. 23 is a transfer curve showing reliability evaluation result of an IGZO thin film according to an embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all form, permutations, equivalents and substitutes covered by the technical ideas and scope of the present disclosure. Accordingly, the embodiments are merely described below, by referring to the figures, to explain features of the present disclosure.

Unless otherwise defined, all technical terms and scientific terms used herein have the same meaning as how they are generally understood by those of ordinary skill in the art to which the present disclosure pertains. However, when the meanings do not match, a description, including a definition, of the present disclosure takes precedence.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

In the present disclosure, an expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

When a component is described to be disposed “on (or below)” an element or “above (or below)” an element, it shall be construed not only as being disposed directly on (or below) the element but also as possibly having another element therebetween.

Any reference to “and/or” shall be construed to include one or more combinations that can be defined by relevant elements.

A size and a thickness of each configuration illustrated in a figure is shown as an example for convenience, and the present disclosure is not limited thereto.

As used herein, [symbol] and [symbol] refer to binding sites.

As used herein, a direct linkage may refer to a chemical bond, such as a single bond.

As used herein, a “substituted or unsubstituted” group may be unsubstituted or substituted with at least one substituent selected from a group containing a deuterium atom, a halogen atom, a nitro group, an amino group, a cyano group, a silyl group, an oxy group, a thio group, a sulfinyl group, a sulfonyl group, a carbonyl group, a boron group, an alkyl group, an alkenyl group, an alkynyl group, an alkoxy group, a phosphine sulfide group, a phosphine oxide group, a hydrocarbon ring group, an aryl group and a heterocyclic group. In addition, each of the substituents presented as examples above may be substituted or unsubstituted. For example, a biphenyl group may be interpreted as an aryl or as a phenyl group substituted with a phenyl group.

As used herein, an alkyl group may have a linear or branched chain. The carbon number of the alkyl group may be 1 to 30, 1 to 20, or 1 to 10. Specific examples include, but not limited to, methyl, ethyl, propyl, n-propyl, isopropyl, butyl, n-butyl, isobutyl, tert-butyl, sec-butyl, 1-methyl-butyl, 1-ethyl-butyl, pentyl, n-pentyl, isopentyl, neopentyl, tert-pentyl, hexyl, n-hexyl, 1-methylpentyl, 2-methylpentyl, 3,3-dimethylbutyl, 2-ethylbutyl, heptyl, n-heptyl, 1-methylhexyl, octyl, n-octyl, tert-octyl, 1-methylheptyl, 2-ethylhexyl, 2-propylpentyl, n-nonyl, 2,2-dimethylheptyl, 1-ethyl-propyl, 1,1-dimethyl-propyl, isohexyl, 2-methylpentyl, 4-methylhexyl, and 5-methylhexyl.

References will now be made in detail to certain embodiments, of which examples are illustrated in the accompanying drawings.

### Precursor Composition for Deposition of Thin Film

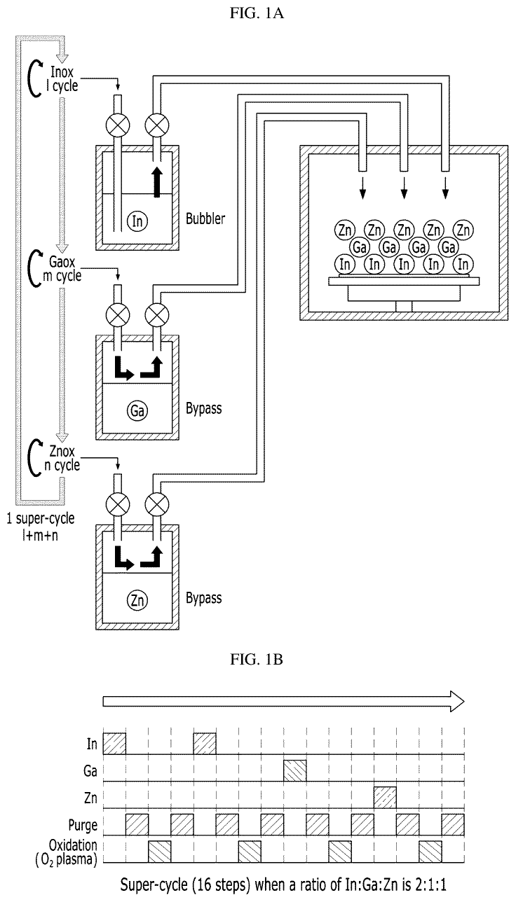

FIG. 1A is a conceptual illustration of a device for manufacturing a thin film by providing a conventional source for deposition of an IGZO thin film, and FIG. 1B is a schematic illustration of a separate process for manufacturing a thin film by sequentially providing sources of three types for deposition of an IGZO thin film by using the device.

According to FIGS. 1A and 1B, a process time for deposition of an IGZO thin film using a conventional source increase because each of In, Ga and Zn sources is separately provided so that 16 steps are needed in one cycle for forming a thin film through atomic layer deposition. Particularly, there is a disadvantage that a separate purging step is required per step of providing each source and time for purging increases.

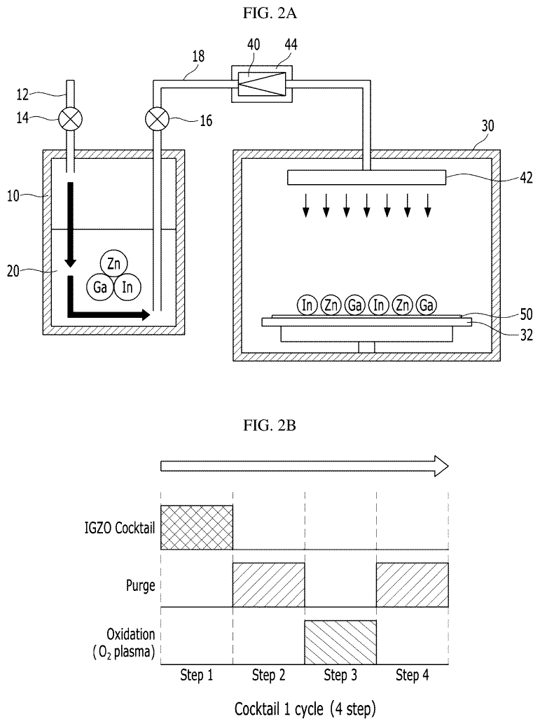

A precursor composition for deposition of a thin film according to the present disclosure is a liquid precursor composition, where liquid indium precursor, liquid gallium precursor and liquid zinc precursor are mixed, for deposition of a thin film. (Hereinafter, it may be also referred as “cocktail.”) A liquid precursor composition for deposition may be vaporized by a vaporizer, and vaporized three-component precursor composition for deposition of a thin film may be introduced (i.e., pulsed) into a chamber as shown in FIG. 2.

A precursor composition for deposition of a thin film according to an aspect of the present disclosure may include liquid indium precursor, liquid gallium precursor, and liquid zinc precursor.

All of the indium precursor, the gallium precursor, and the zinc precursor are alkyl-based materials which is suitable for mixing with ease and adjusting a flow rate without a side reaction and with a similar vaporization temperature, but the present disclosure is not limited thereto.

There has been a disadvantage that a conventional halogen-based precursor requires deposition at a temperature of 300° C. or more due to high thermal stability and it is difficult to mix in a liquid state.

A precursor composition for deposition of a thin film according to the present disclosure is an alkyl-based precursor that does not cause contamination by a halogen because a halogen is not included and has excellent thermal stability so that it is easy to form a thin film at a low temperature, but the present disclosure is not limited thereto.

A molar ratio of indium:gallium:zinc in the precursor composition for deposition of a thin film may be 0.1 to 10:0.1 to 10:0.1 to 10, but the present disclosure is not limited thereto. A molar ratio of indium:gallium:zinc in an IGZO thin film manufactured using the precursor composition for deposition of a thin film may be suitably 0.1 to 10:0.1 to 10:0.1 to 10, more suitably 1 to 5:1 to 5:1 to 5, even more suitably 1 to 3:1 to 3:1 to 3, yet even more suitably 1 to 2:1 to 2:1 to 2, and most suitably 1:1:1, but the present disclosure is not limited thereto. A reactivity of each element precursor may be different so that, when a thin film is formed by a single cycle process with the three-component based mixed precursor composition for deposition of an IGZO thin film, a molar ratio of indium:gallium:zinc in the IGZO thin film may be different. Particularly, a reactivity of gallium is relatively lower than that of indium or zinc. Accordingly, it may be possible to increase molar concentration of gallium, which has a lower reactivity, in the precursor composition than a molar concentration of indium or zinc in the precursor composition. Although the present disclosure is not limited thereto, a molar ratio of indium:gallium:zinc in the precursor composition for deposition of a thin film may be 1:1:1 to 1:3:1. In addition, a ratio of an element included in a thin film may be suitably adjusted by controlling a process condition for forming a thin film.

Although the present disclosure is not limited thereto, the liquid indium precursor may be at least one species selected from triethylindium, tryisopropylindium, and tri (tert-butyl) indium. The triethylindium, triisopropylindium and tri (tert-butyl) indium are as shown in Formula 1 through 3 below.

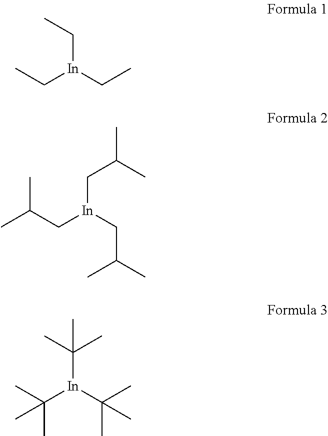

Although the present disclosure is not limited thereto, the triethylindium as the liquid indium precursor may be suitable for deposition of indium because it has excellent reactivity and a thin film formed using the triethylindium has improved electron mobility and reliability.

Although the present disclosure is not limited thereto, the liquid gallium precursor may be trimethylgallium or triethylgallium, and the trimethylgallium may be suitable for reliability improvement of a three-component-based thin film.

Although the present disclosure is not limited thereto, the liquid zinc precursor may be diethylzinc or dimethylzinc, and the diethylzinc may be suitable for reliability improvement of a thin film.

Although the present disclosure is not limited thereto, the precursor composition may not include a solvent. All of precursor composition according to the present disclosure may have a liquid state so that it may be easily applicable to liquid delivery system (LDS) even without a solvent.

According to the above configuration of the present disclosure, a thin film may be formed through a single-cycle supply of a vaporized three-component based mixed precursor composition for deposition of an IGZO thin film. Accordingly, it is economically advantageous for a process for manufacturing a thin film as the process of the present disclosure may be simple and an overall process time may be drastically reduced when compared to the conventional technique, where each element of a precursor composition for deposition of a thin film is supplied through three to four cycles and purging of each element of each composition precursor is implemented per supply as shown in FIGS. 1A and 1B.

Hereinafter, the present disclosure is more specifically described referring to FIGS. 2A and 2B.

FIG. 2A is a conceptual illustration of a device for manufacturing a thin film by providing a liquid three-component based mixed precursor composition for deposition of an IGZO thin film according to an embodiment of the present disclosure through liquid delivery system (LDS) and simultaneously providing gaseous indium precursor, gallium precursor, and zinc precursor, which are vaporized by a vaporizer, on a substrate. FIG. 2B is a schematic illustration of a separate process for manufacturing a thin film by providing a three-component based mixed precursor composition for deposition of an IGZO thin film by using the device.

According to FIG. 2A, a device for manufacturing an oxide semiconductor thin film according to an embodiment of the present disclosure may include a chamber 30 configured to load a substrate 50 where an oxide semiconductor thin film, such as an IGZO thin film, is formed, and supply system of a source material for deposition of a thin film configured to provide a gaseous precursor composition for deposition of a thin film into the chamber 30.

The supply system of a source material may include a precursor composition container 10 in which a precursor composition for deposition 20 is stored, a carrier gas supply unit 12, a valve 14 and 16, and a precursor composition supply unit 18.

The precursor composition container 10 may be configured to store a liquid three-component based mixed precursor composition 20 for deposition of an IGZO thin film, and be referred as a canister. The carrier gas supply unit 12 may be configured to provide carrier gas into the precursor composition container 10. The precursor composition supply unit 18 may be configured to provide the gaseous precursor composition generated in the container 10 into the chamber 30. The carrier gas supply unit 12 and the precursor composition supply unit 18 may be respectively connected to valves 14 and 16 which are configured to control a flow rate by opening and closing the valves 14 and 16. The composition for deposition of a thin film provided through the precursor composition supply unit 18 may be vaporized into a gaseous state by a vaporizer 40, and the vaporizer 40 may be heated by a heater 44 to 30° C. to 80° C. so that a temperature of a substrate 50 may be heated to 100° C. to 350° C.

Although the present disclosure is not limited thereto, a mixture of the liquid indium precursor, liquid gallium precursor, and liquid zinc precursor may be supplied to a substrate through a liquid delivery system (LDS) which delivers a mixture of the liquid indium precursor, liquid gallium precursor, and liquid zinc precursor at a room temperature and vaporizes the mixture of the liquid indium precursor, liquid gallium precursor, and liquid zinc precursor with a vaporizer for deposition. Various supply method including liquid mass flow controller (LMFC) method may be applied.

Space for formation of an oxide semiconductor thin film, such as an IGZO thin film, may be provided in the chamber 30. A stage 32, where a substrate 50 may be seated so that an oxide semiconductor thin film, such as an IGZO thin film, may be formed, may be provided at the bottom of an inner surface of the chamber 30. A shower head 42 may be arranged in the upper side of the inner surface of the chamber 30 and configured to supply the vaporized gaseous three-component based mixed precursor composition for deposition of an IGZO thin film.

Although the present disclosure is not limited thereto, the chamber 30 may be provided with at least one plasma supply device (not shown), and the at least one plasma supply device may be arranged along a transport direction of a substrate. The plasma supply device may convert argon and/or helium into plasma which includes a positive ion and an electron to form high energy electrons to deposit a thin film on a substrate through conversion of discharged gas, for example, ozone charged in the chamber 30, into a plasma state.

In addition, referring to FIG. 2B, one cycle of deposition of a thin film may include 4 steps that include a process of forming an IGZO thin film on the substrate by providing IGZO cocktail into the chamber 30 through the shower head 42, a purging process using inert gas, an oxidation process using O₂ plasma, and a purging process using inert gas.

### Manufacturing Method of Thin Film

A manufacturing method of a thin film according to the present disclosure may include i) obtaining a precursor composition for deposition of a thin film by mixing liquid indium precursor, liquid gallium precursor, and liquid zinc precursor, ii) forming a thin film on a substrate by using the precursor composition for deposition of a thin film, iii) first purging a chamber with inert gas, iv) oxidizing the thin film by using reactive gas, and v) second purging the chamber with inert gas.

Hereinafter, each step is specifically described.

The step i) is a step of obtaining a precursor composition for deposition of a thin film by mixing liquid indium precursor, liquid gallium precursor, and liquid zinc precursor.

All of the liquid indium precursor, liquid gallium precursor, and liquid zinc precursor are alkyl-based materials which is suitable for mixing with ease and controlling flow rate without a side reaction and with similar vaporization temperate, but the present disclosure is not limited thereto.

A conventional halogen-based precursor has a disadvantage that its deposition requires a temperature of 300° C. or more due to its high thermal stability and it is difficult to be mixed in a liquid state.

The precursor composition for deposition of a thin film according to the present disclosure is an alkyl-based precursor that does not include halogen and therefore does not cause contamination and has excellent thermostability so that it is easy to form a thin film at a low temperature.

Indium, gallium, and zinc in the precursor composition for deposition of a thin film in the step i) may include a molar ratio of 0.1 to 10:0.1 to 10:0.1 to 10, but the present disclosure is not limited thereto.

An element composition of an IGZO thin film manufactured using the precursor composition for deposition of a thin film according to the present disclosure may have a molar ratio of indium:gallium:zinc suitably as 0.1 to 10:0.1 to 10:0.1 to 10, more suitably as 1 to 5:1 to 5:1 to 5, even more suitably as 1 to 3:1 to 3:1 to 3, and yet even more suitably as 1 to 2:1 to 2:1 to 2, and most suitably as 1:1:1.

A reactivity of a precursor of each element may be different so that a molar ratio of indium:gallium;zinc in the IGZO thin film may be different when a thin film is formed through a single cycle process with the three-component based mixed precursor composition for deposition of an IGZO thin film. Particularly, a reactivity of gallium is relatively lower than that of indium or zinc. Accordingly, molecular concentration of gallium, which has low reactivity, in the precursor composition may be controlled to be greater than that of indium and zinc. A molar ratio of indium:gallium:zinc in the precursor composition for deposition of a thin film may be between 1:1:1 and 1:3:1, but the present disclosure is not limited thereto. In addition, it may be able to control a ratio of an element included in a thin film by controlling a process condition of forming a thin film.

The liquid indium precursor may be at least one species selected from triethylindium, triisopropylindium, and tri (tert-butyl) indium, but the present disclosure is not limited thereto. The trietylindium, triisopropylindium, and tri (tert-butyl) indium are Formula 1 through 3 as shown below.

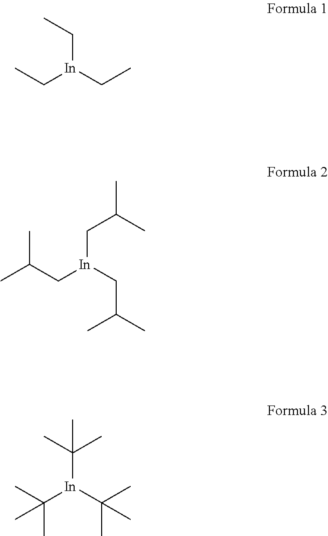

Although the present disclosure is not limited thereto, the triethylindium as liquid indium precursor is suitable for mobility of a thin film and reliability improvement as it has excellent reactivity and is suitable for deposition of indium.

Although the present disclosure is not limited thereto, the liquid gallium precursor may be the trimethylgallium or triethylgallium, and trimethyl gallium may be suitable for reliability improvement of a thin film.

Although the present disclosure is not limited thereto, the liquid zinc precursor may be diethylzinc or dimethylzinc, and the diethylzinc may be suitable for reliability improvement of a thin film.

Although the present disclosure is not limited thereto, the liquid precursor composition for deposition of a thin film may not include a solvent. All of the precursor according to the present disclosure may be a liquid state so that it is easily transferred by a liquid delivery system (LDS) even without a solvent.

Below, the step ii) is a step for forming a thin film on a substrate by using the precursor composition for deposition of a thin film.

Although it is not limited thereto, in the step ii), a thin film may be formed through atomic layer deposition (ALD) or chemical vapor deposition (CVD) using the precursor composition for deposition of a thin film. Although it is not limited thereto, a thin film may be formed through plasma-enhanced atomic layer deposition (PEALD) or metal-organic chemical vapor deposition (MOCVD) with the precursor composition for deposition of a thin film.

Although it is not limited thereto, a thin film may be formed at a temperature between 100° C. and 300° C. through atomic layer deposition (ALD) or chemical vapor deposition by using the precursor composition for deposition of a thin film. Although it is not limited thereto, the temperature for forming a thin film in the step ii) may be suitably between 100° C. and 300° C. for formation of a thin film with excellent film quality. When the temperature for formation of the thin film is less than 100° C., precursor is not sufficiently activated so that a deposition rate of the thin film decreases. When the temperature for formation of the thin film is higher than 300° C., indium precursor, zinc precursor, or gallium precursor may be thermally degraded, and therefore it is not suitable.

Although it is not limited thereto, in the step ii), a thin film may be formed by vaporizing the precursor composition for deposition of a thin film with a vaporizer. Although the present disclosure is not limited thereto, a mixture of the liquid indium precursor, liquid gallium precursor, and liquid zinc precursor may be transferred to a substrate through liquid delivery system (LDS) which transfers a liquid state mixture of the liquid indium precursor, liquid gallium precursor, and liquid zinc precursor at a room temperature and vaporized by a vaporizer for deposition. Various supply methods, such as direct liquid injection (DLI) for direct spray, vapor flow controller (VFC) for direct supply by using vapor pressure of precursor, or liquid mass flow controller (LMFC), may be implemented.

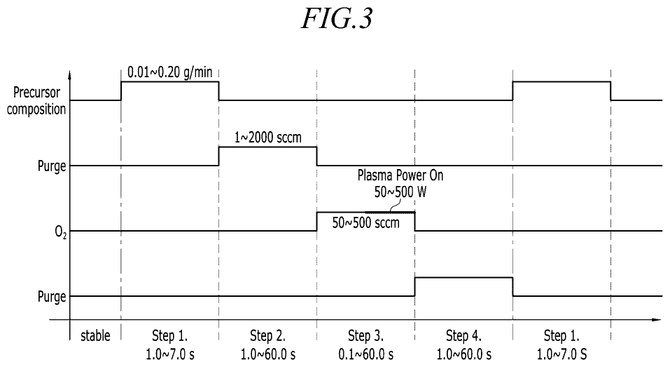

FIG. 2A is a conceptual illustration of a device for manufacturing a thin film by providing a three-component based mixed precursor composition for deposition of an IGZO thin film according to an embodiment of the present disclosure through liquid delivery system (LDS) and simultaneously providing indium precursor, gallium precursor, and zinc precursor vaporized by a vaporizer on a substrate. FIG. 3 is an illustration of gaseous flow according to each step for forming an IGZO thin film by atomic layer deposition through liquid delivery system of the device shown in FIG. 2A according to an embodiment of the present disclosure. Although it is not limited thereto, a device for manufacturing the thin film shown in FIG. 2A may be used for formation of a thin film through the steps shown in FIG. 3.

FIG. 2B is a schematic illustration of a separate process for manufacturing a thin film by providing a three-component based mixed precursor composition for deposition of an IGZO thin film by using the device. Referring to FIG. 2B, one cycle for deposition of a thin film may be completed with four steps, where the gaseous three-component based mixed precursor composition for deposition of an IGZO thin film injected from a shower head 42 may be deposited on a substrate 50, and purged with inert gas, and the thin film is subsequently oxidized by using plasma and purged again with inert gas.

As described above, in the step ii), the precursor composition for deposition of a thin film is vaporized by a vaporizer so that the precursor may be provided to the chamber 30 in a gaseous state.

Referring to FIG. 3, the precursor composition 20 manufactured in the step i) and stored in a precursor composition container 10 may be transported to a vaporizer through a precursor composition supply unit 18 by a carrier gas provided through a carrier gas supply unit 12. (See step 1 in FIG. 3) Although it is not limited thereto, the precursor composition may be provided at a speed between 0.01 g/min and 0.20 g/min for between 1.0 second and 7.0 seconds.

The three-component based mixed precursor composition for deposition of an IGZO thin film transported by the precursor composition supply unit 18 may be vaporized by a vaporizer 40, which is heated to between 30° C. and 80° C. by a heater 44, so that the gaseous three-component based mixed precursor composition for deposition of an IGZO thin film may be provided into the chamber 30, and a temperature of the substrate 50 may be heated to between 100° C. and 350° C.

When a liquid three-component based mixed precursor composition for deposition of an IGZO thin film is provided to the chamber 30, homogeneity of a thin film may be negatively affected. Therefore, it would be suitable to vaporize the liquid three-component based mixed precursor composition for deposition of an IGZO thin film and provide it to the chamber. In addition, when a vaporizer 40 configured to vaporize the liquid three-component based mixed precursor composition for deposition of an IGZO thin film and a heater 44 configured to heat the vaporizer 40 are provided outside of the chamber 30, a temperature of the chamber 30 may not be affected by the heater 44 so that the temperature of the chamber 30 may be easily controlled. The gaseous three-component based mixed precursor composition for deposition of an IGZO thin film introduced to the chamber 30 may be injected by a shower head 42 toward s substrate 50 to be deposited on a substrate 50. Here, indium, gallium and zinc included in the gaseous three-component based mixed precursor composition for deposition of an IGZO thin film may be uniformly mixed and deposited on the substrate 50.

As described above, when the three-component based mixed precursor composition for deposition of an IGZO thin film is simultaneously provided through liquid delivery system (LDS) for deposition of a thin film, indium precursor, gallium precursor, and zinc precursor may be simultaneously injected to the substrate to form a mixed single-layer thin film. In addition, it is possible to introduce the indium precursor, gallium precursor, and zinc precursor of a large amount over a large area so that the precursor composition is supplied at a uniform concentration during deposition to form a uniform film.

The step iii) is a step of first purging with inert gas (see Step 2 in FIG. 3). The first purging is a step of supplying inert gas into the chamber 30 for removing a gaseous precursor composition undeposited on the substrate 50. Although it is not limited thereto, the inert gas may be, for example, argon, helium, nitrogen, or neon. Although it is not limited thereto, a flow rate of the inert gas may be between 1 sccm and 2,000 sccm. Although it is not limited thereto, the first purging may be implemented for between 1.0 second and 60.0 seconds. During the first purging, an impurity including remaining three-component based mixed precursor composition for deposition of an IGZO thin film may be removed.

The step iv) is a step of oxidizing a thin film by using reactive gas (see Step 3 in FIG. 3). Although it is not limited thereto, oxidization of a thin film may use oxygen plasma. Although it is not limited thereto, oxygen may be supplied with a supply flow rate of between 50 sccm and 500 sccm at a power of between 50 W and 500 W to implement a plasma process. Although it is not limited thereto, the oxidizing step may be implemented for between 1.0 second and 60.0 seconds. Although it is not limited thereto, in the first period (between 1 second and 7 seconds) of supplying an O₂ source material into the reaction chamber, the O₂ source material is supplied into the reaction chamber while plasma is not formed in the reaction chamber. Accordingly, an atmosphere of an O₂ source material may be formed inside the reaction chamber, and the O₂ source material may be attached on the three-component based mixed precursor composition for deposition of an IGZO thin film.

In addition, in the second period of supplying an O₂ source material into the reaction chamber, the O₂ source may be supplied into the reaction chamber to form plasma. Although it is not limited thereto, argon may be supplied in the first period and the second period of supplying an O₂ source material into the reaction chamber, and a flow rate of argon may be between 50 sccm and 500 sccm or between 100 sccm and 300 sccm. As above, when plasma is generated in the reaction chamber, O₂ atoms are ionized to form much more bindings with In—Ga—Zn atoms on a surface of a substrate, and the source materials may react on the surface of the substrate to deposit an IGZO-based thin film. Although it is not limited thereto, a flow rate of an O₂ source material may be between 100 sccm and 300 sccm, the supply time may be between 3 seconds and 10 seconds, and a plasma power may be between 100 W and 300 W. By controlling on-off period of plasma, an amount of the O₂ source material supplied into the reaction chamber may be controlled.

In the step iv), a flow rate of the reactive gas may be between 50 sccm and 500 sccm, and the supply time of the reactive gas may be between 0.1 seconds and 60.0 seconds.

The step v) is a step of second purging with inert gas (see Step 4 in FIG. 3). In the step v), the reactive gas in the step iv) is removed by using inert gas. Although it is not limited thereto, the second purging may be carried out by supplying the inert gas of between 1 sccm and 2,000 sccm for between 1.0 second and 60.0 seconds. An impurity including, for example, an O₂ source material remaining in the reaction chamber may be removed through the second purging.

Although it is not limited thereto, it may be suitable for manufacturing a thin film with an excellent quality that deposition with one cycle including the step ii) through step v) may be performed in between 200 and 600 cycles, more suitably in between 200 and 500 cycles, and even more suitably in between 200 and 400 cycles. Although it is not limited thereto, when the number of deposition is less than 200 cycles, deposition of a thin film may be insufficiently performed. When the number of deposition is more than 600 cycles, a thickness of an IGZO thin film may become thicker. When the thickness of the thin film becomes thicker, a property of a thin film transistor (TFT) channel may be affected, and therefore it may be unsuitable.

When a conventional precursor composition for deposition of an IGZO thin film is deposited through a by-pass method, an indium precursor, a gallium precursor, and a zinc precursor may be successively discharged to a substrate based on a vaporization pressure so that a process of 16 steps is required. Compared to the above, when deposition is performed through liquid delivery system (LDS) method by using a liquid three-component based mixed precursor composition for deposition of an IGZO thin film according to an embodiment of the present disclosure, the process may be reduced to 4 steps.

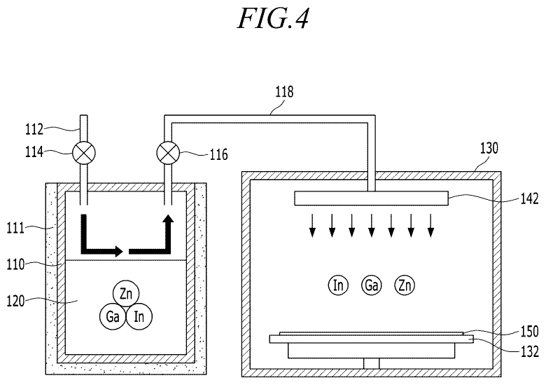

FIG. 4 is a conceptual illustration of a device for manufacturing a thin film by providing a three-component based mixed precursor composition for deposition of an IGZO thin film according to an embodiment of the present disclosure through a by-pass method and successively providing vaporized gaseous indium precursor, gallium precursor, and zinc precursor on a substrate according to a vaporization pressure.

Referring to FIG. 4, a device for manufacturing an oxide semiconductor thin film according to an embodiment of the present disclosure may include a chamber 130 configured to load a substrate 150 where an oxide semiconductor thin film, such as an IGZO thin film, is to be formed and a supply system of a source material for deposition of a thin film configured to provide a gaseous three-component based mixed precursor composition for deposition of an IGZO thin film into the chamber 130.

The supply system of a source material may include a precursor composition container 110, a carrier gas supply unit 112, valves 114 and 116, a precursor composition supply unit 118, and a precursor composition for deposition 120.

The precursor composition container 110 may be configured to store a liquid three-component based mixed precursor composition for deposition of an IGZO thin film and referred as a canister. The carrier gas supply unit 112 may be configured to supply carrier gas into the precursor composition container 110. The precursor composition supply unit 118 may be configured to supply gaseous precursor composition, which is generated by heating the precursor composition 120 by a heater 111 which is provided outside of the precursor composition container 110, into the chamber 130. A valve 114 and 116 may be respectively connected to the carrier gas supply unit 112 and the precursor composition supply unit 118 and configured to control opening of a flow path to control a flow of a fluid.

The chamber 130 may be provided with a space for formation of an oxide semiconductor thin film, such as an IGZO thin film, and a stage 132 may be provided on a bottom side in the chamber 130 for placement of a substrate 150 to form an oxide semiconductor thin film, such as an IGZO thin film. A shower head 142 configured to provide the gaseous three-component based mixed precursor composition for deposition of an IGZO thin film on the substrate 150 by injecting may be placed in an upper side in the chamber 130.

According to the system with the above configuration, indium, gallium and zinc in a liquid three-component based mixed precursor composition for deposition of a GIZO thin film may be successively discharged according to a vaporization pressure to form an IGZO mixed thin film.

When deposition is performed through a liquid delivery system (LDS) method by using a liquid three-component based precursor composition for deposition of an IGZO thin film according to an embodiment of the present disclosure, the process may be reduced to 4 steps, and when compared to a by-pass process, a more uniformly mixed single-layer thin film may be deposited and an amorphous multi-element oxide thin film may be deposited.

### Thin Film

A thin film according to another aspect of the present disclosure may be a thin film formed on a substrate by using a precursor composition for deposition of a thin film including liquid indium precursor, liquid gallium precursor and liquid zinc precursor, and the thin film may be a single layer of a mixture of indium, gallium and zinc and amorphous.

Although the present disclosure is not limited thereto, the thin film may be a thin film formed by atomic layer deposition or chemical vapor deposition by using the precursor composition for deposition of a thin film. Although the present disclosure is not limited thereto, the thin film may be a thin film formed by metal-organic chemical vapor deposition.

Although the present disclosure is not limited thereto, an element composition of an IGZO thin film formed using a precursor composition for deposition of a thin film may have a molar ratio of indium:gallium:zinc suitably as 0.1 to 10:0.1 to 10:0.1 to 10, more suitably as 1 to 5:1 to 5:1 to 5, even more suitably as 1 to 3:1 to 3:1 to 3, yet even more suitably as 1 to 2:1 to 2:1 to 2, and most suitably as 1:1:1. Although the present disclosure is not limited thereto, a molar ratio of indium, gallium and zinc may be controlled during the process of manufacturing a precursor composition for deposition of a thin film, or a ratio of an element included in a thin film may be suitably controlled by controlling a condition of a process of forming a thin film.

Although the present disclosure is not limited thereto, a content ratio of indium in the thin film may be 10 wt % or more. According to the above configuration, there is an advantage that electron mobility of a thin film increases as a content of indium increases.

Although the present disclosure is not limited thereto, a thin film formed through atomic layer deposition according to an embodiment of the present disclosure may have less void and therefore have much higher density than a thin film formed through a PVD method (sputtering).

Although the present disclosure is not limited thereto, a thin film formed through atomic layer deposition according to an embodiment of the present disclosure may have much less surface roughness than a thin film formed through PVD (sputtering). Although the present disclosure is not limited thereto, a root-mean-square surface roughness (RMS) of a thin film formed through atomic layer deposition according to an embodiment of the present disclosure maybe 1.20 nm or less when a thickness of the thin film is between 30 nm and 50 nm.

A thin film formed through atomic layer deposition according to an embodiment of the present disclosure may have an excellent refractive index between 1.5 and 2.5 or between 1.7 and 2.2 with light of a 632 nm wavelength.

### Electronic Device Including Thin Film

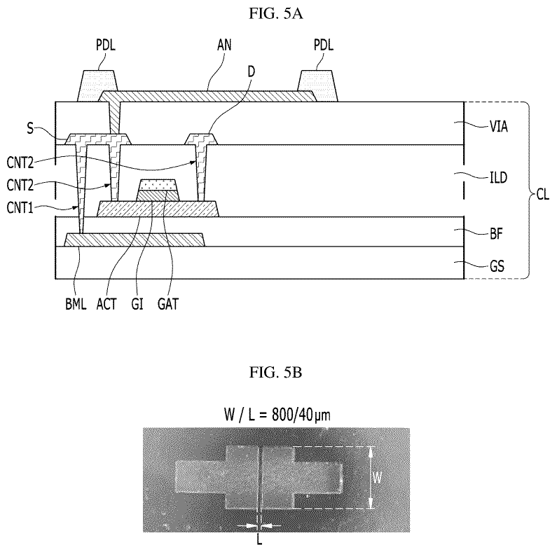

FIG. 5A is a schematic cross-sectional view of a thin film transistor including an IGZO thin film formed by using a three-component based mixed precursor composition for deposition of an IGZO thin film according to an embodiment of the present disclosure, and FIG. 5B is a schematic top view of the thin film transistor.

Referring to FIG. 5A, a highly doped Si substrate GS with a SiO₂ buffer layer BF formed with a thickness of 100 nm on the substrate is used, an active layer ACT is formed by deposition of an IGZO thin film on the SiO₂ buffer layer BF, and a thin film transistor including a source electrode S and a drain electrode D positioned to face each other on the active layer ACT is manufactured. The circuit layer CL may include a buffer layer BF, an active layer ACT, a gate insulating layer GI, a gate electrode GAT, an interlayer insulating layer ILD, a source electrode S, a drain electrode D and a via insulating layer VIA.

The substrate GS may include various materials, such as glass, metal or plastic. According to an embodiment of the present disclosure, the substrate GS may include a flexible material. Herein, the flexible material may be a material that may be easily curved, bent, folded or rolled. For example, the flexible material may include ultra-thin glass, metal or plastic.

A lower metallic layer BML may be arranged on the substrate GS. A buffer layer BF may be arranged on the lower metallic layer BML, and an active layer ACT may be arranged on the buffer layer BF. The lower metallic layer BML may overlap at least partially with a thin film transistor arranged on an upper side of the lower metallic layer BML. More particularly, the lower metallic layer BML may overlap at least partially with an active layer ACT arranged on an upper side of the lower metallic layer BML.

When the active layer ACT includes an oxide semiconductor material, the active layer ACT may have a property of being vulnerable to light. As the lower metallic layer BML is arranged below the active layer ACT, photocurrent caused by external light incident from the substrate side to the active layer ACT may be prevented from occurring, thus a change of a device property of a thin film transistor may be minimized.

A gate insulating layer GI may be arranged on the active layer ACT, and a gate electrode GAT may be arranged on the gate insulating layer GI. In addition, an interlayer insulating layer ILD may be arranged on the gate electrode GAT. For example, the interlayer insulating layer ILD may be provided to cover elements arranged below.

A via insulating layer VIA may be arranged on the interlayer insulating layer ILD, and a pixel electrode AN may be arranged on the via insulating layer VIA.

The pixel electrode AN may be electrically connected to a source electrode S through a via hole defined in the via insulating layer VIA.

The pixel electrode AN may be a (semi) transmissive electrode or a reflective electrode. In an embodiment, the pixel electrode AN may be provided with a reflective layer formed with, for example, Ag, Mg, Al, Pt, Pd, Au, Ni, Nd, Ir, Cr, or a compound thereof, and a transparent or translucent electrode layer formed on the reflective layer. The transparent or translucent electrode layer may be provided with at least one selected from the group consisting of indium tin oxide (ITO), indium zinc oxide (IZO), zinc oxide (ZnO), indium oxide (In₂O₃), indium gallium oxide (IGO) and aluminum zinc oxide (AZO). For example, the pixel electrode AN may be provided as ITO/Ag/ITO.

A pixel defining film PDL may be arranged on the pixel electrode AN. The pixel defining film PDL may be formed with an organic insulating material of at least one selected from the group consisting of polyimide, polyamide, acrylic resin, benzocyclobutene and phenol resin through a method, such as spin coating.

In an embodiment, the source electrode S may be electrically connected to the lower metallic layer BML through a first contact hole CNT1 defined in the buffer layer BF and the interlayer insulating layer ILD.

In an embodiment, the source electrode S and the drain electrode D may be electrically connected to the active layer ACT through a second contact hole CNT2 defined in the interlayer insulating layer ILD.

The active layer ACT may include at least one of an oxide semiconductor material and a silicon semiconductor material. When the active layer ACT includes an oxide semiconductor material, the active layer ACT may include an oxide material of at least one material selected from a group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Ce) and zinc (Zn). For example, the active layer ACT may include, for example, IGZO (In—Ga—Zn—O), ITZO (In—Sn—Zn—O), or IGTZO (In—Ga—Sn—Zn—O) containing a metal, such as indium (In), gallium (Ga) and tin (Sn), in an oxide zinc (ZnO). In the present disclosure, it may be suitable that the active layer ACT may include In—Ga—Zn—O (IGZO).

The gate insulating layer GI formed on the active layer ACT may include at least one of silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂) and zinc oxide (ZnO_{X}). Herein, the zinc oxide (ZnO_{X}) may be oxide zinc (ZnO) and/or zinc peroxide (ZnO₂).

The gate electrode GAT may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W) or copper (Cu) and formed of a single layer or multiple layers of one or more materials.

Although the present disclosure is not limited thereto, the interlayer insulating layer ILD may include at least one of silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), and zinc oxide (ZnO_{X}). Here, the zinc oxide (ZnO_{X}) may be zinc oxide (ZnO) and/or zinc peroxide (ZnO₂).

Referring to FIG. 5B, the thin film transistor may be formed to have a width W of 800 μm and length L of 40 μm.

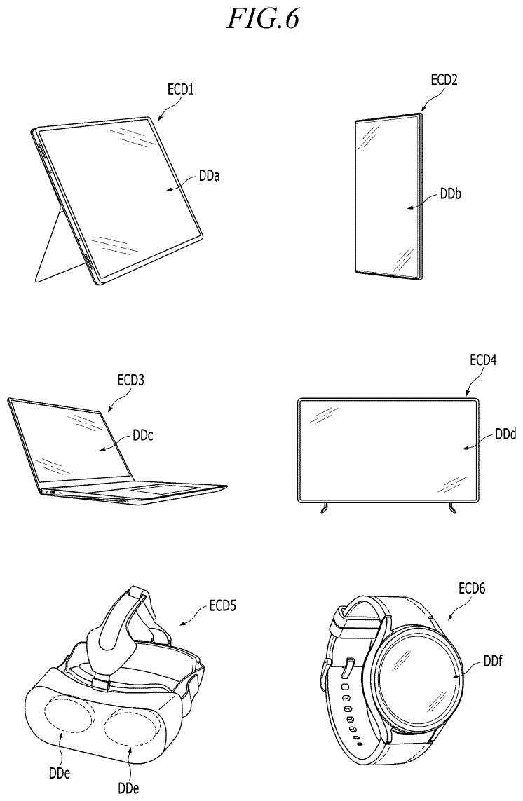

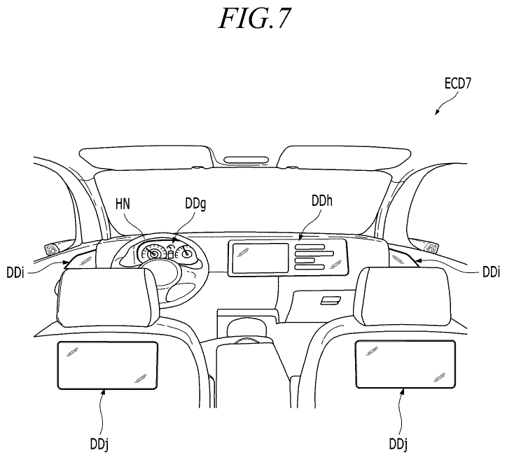

FIGS. 6 and 7 are illustration of an electronic device including a thin film transistor according to an embodiment of the present disclosure.

Referring to FIG. 6, a first electronic device ECD1 is illustrated as a tablet including a first display device Dda. A second electronic device ECD2 is illustrated as a portable terminal including a second display device DDb. A third electronic device ECD3 is illustrated as a laptop including a third display device DDc. A fourth electronic device ECD is illustrated as a television including a fourth display device DDd. A fifth electronic device ECD5 is illustrated as a head mounted display device including a fifth display device DDe. A sixth electronic device ECD6 is illustrated as a digital watch including a sixth display device DDf.

Referring to FIG. 7, a seventh electronic device ECD7 is illustrated as a vehicle including a seventh display device through a tenth display device DDg through DDj. A seventh electronic device ECD7 is exemplarily illustrated as a vehicle, but the present disclosure is not limited to what is shown in the figure. The seventh electronic device ECD7 may be various transportation means, such as a bicycle, a motorcycle, a train, a ship or a plane.

Referring to FIGS. 5A, 6, and 7, the first electronic device through the seventh electronic device ECD1 through ECD7 according to another aspect of the present disclosure may include a substrate GS and a circuit layer CL arranged on the substrate GS and including a transistor. The transistor may include an active layer ACT, and the active layer ACT may be a thin film formed by using a precursor composition for deposition of a thin film including liquid indium precursor, liquid gallium precursor, and liquid zinc precursor.

Other than the electronic devices shown in FIGS. 6 and 7, an electronic device according to an embodiment is not limited to what is shown in the figures and may be applicable to various electronic devices such as a plane panel display, a curved display, a television, a billboard, a computer monitor, a medical monitor, a head mounted display (HMD), an indoor or outdoor lighting or light for signal, a wearable device, a foldable device, a rollable device, a bendable device, a flexible device, a curved device, an electronic notebook, an electronic book, a portable multimedia player (PMP), a personal digital assistant (PDA), a laser printer, a telephone, a cellphone, a tablet, a portable terminal, a notebook, a laptop, a digital camera, a viewfinder, a camcorder, a 3D display, a virtual reality or augmented reality display, a video wall containing multiple displays tiled together, a vehicle, an outdoor display device, a theater or stadium screen, and a signboard.

Hereinafter, Examples of the present disclosure and Comparative Examples are described. A precursor composition according to an embodiment, a manufacturing method of a thin film using the same, a thin film manufactured using the manufacturing method and an electronic device including the thin film will be specifically described. However, Examples shown below are shown merely for the understanding of the present disclosure, and the scope of the present disclosure is not limited thereto.

### EXAMPLE

### Example 1. Manufacture of Thin Film Using Three-Component Based Mixed Precursor Composition for Deposition of IGZO Thin Film

Liquid indium precursor, liquid gallium precursor, and liquid zinc precursor were mixed to manufacture a three-component precursor composition for deposition of an IGZO thin film. Here, the indium precursor might be triethylindium, the gallium precursor might be trimethylgallium (TMG), the zinc precursor might be diethylzinc (DEZ) for manufacture of a three-component based mixed precursor composition for deposition of an IGZO thin film. Triethylindium, trimethylgallium, and diethylzinc were mixed with a molar ratio of 1:1:1 for manufacture of an IGZO precursor composition. The three-component based mixed precursor composition for deposition of an IGZO thin film was provided through liquid delivery system (LDS) to manufacture a thin film by simultaneously providing gaseous indium precursor, gallium precursor, and zinc precursor, which are vaporized with a vaporizer, on a substrate.

### Comparative Example 1

A thin film was manufactured in the same way as in Example 1 except for using (3-dimethylaminopropyl)dimethylindium (DADI) as indium precursor.

### Comparative Example 2

A thin film was manufactured in the same way as in Example 1 except for using trimethylindium (TMI) as indium precursor.

A type of indium precursor in Example 1 and Comparative Examples 1 and 2, and Indium composition ratio of a thin film manufactured using Example 1 and Comparative Examples 1 and 2 are shown in Table 1.

TABLE 1

| | | Indium |
|---|---|---|
| | | Composition |
| | | Ratio in |
| | | IGZO Thin |
| Category | Type of Indium Precursor (In source) | Film |
| Comparative | 3-dimethylaminopropyl)dimethylindium | 2% |
| Example 1 | (DADI) | |
| Comparative | trimethylindium (TMI) | 0% |
| Example 2 | | |
| Example 1 | triethylindium (TEI) | 15% |

According to Table 1 above, when triethyl indium (TEI) was indium precursor in Example 1, an indium composition ratio of a thin film was 15%, which was greater than that of Comparative Example 1, where indium precursor was DADI, and Comparative Example 2, where indium precursor was TMI. Accordingly, in order to form a thin film with a liquid, mixed precursor composition, it may be suitable to have triethylindium (TEI) as indium precursor.

### Example 2. Manufacture of Thin Film Using Three-Component Based Mixed Precursor Composition for Deposition of IGZO Thin Film

A step of manufacturing a thin film by using a three-component based mixed precursor composition for deposition of an IGZO thin film includes a first step through a fourth step. In the first step (Step 1), a temperature of a substrate provided inside a reaction chamber was heated to between 100° C. and 350° C., a phase of the three-component based mixed precursor composition for deposition of an IGZO thin film manufactured in Example 1 was changed to gas by a vaporizer, and the three-component based mixed precursor composition for deposition of an IGZO thin film was provided on a substrate at 0.05 g/min for 1 second. A standard pressure in the first step (Step 1) was 0.005 Torr while a process pressure was 0.5 Torr. In the second step (Step 2), argon gas (100 sccm) was provided into the reaction chamber as purge gas for 5 seconds for a first purging process. In the third step (Step 3), an O₂ source material was provided into the reaction chamber at 100 sccm for 1 second. Subsequently, in the fourth step (Step 4), argon gas (100 sccm) was provided into the reaction chamber as a purging gas for 5 seconds for a second purging process.

### Example 3. Manufacture of Thin Film Using Three-Component Based Mixed Precursor Composition for Deposition of IGZO Thin Film

A step for manufacturing a thin film using the three-component based mixed precursor composition for deposition of an IGZO thin film is the same as in Example 2 except for a condition of the step below. A standard pressure in the first step (Step 1) was 0.005 Torr while a process pressure was 1.0 Torr. The three-component precursor composition for deposition of an IGZO thin film was provided on a substrate at 0.10 g/min for 1 second. In the second step (Step 2), argon gas (100 sccm) was provided into the reaction chamber as purge gas for 30 seconds for a first purging process. In the third step (Step 3), an O₂ plasma source material was provided into the reaction chamber at 200 sccm for 5 seconds. Subsequently, argon gas (100 sccm) was provided into the reaction chamber as purge gas for 30 seconds for a second purging process.

### Example 4. Manufacture of Thin Film Using Three-Component Based Mixed Precursor Composition for Deposition of IGZO Thin Film

A step for manufacturing a thin film using the three-component based mixed precursor composition for deposition of an IGZO thin film is the same as in Example 3 except for a supplying the three-component based mixed precursor composition for deposition of an IGZO thin film on a substrate at 0.10 g/min for 3 seconds.

Process conditions for manufacturing a thin film using a three-component based mixed precursor composition for deposition of an IGZO thin film in Examples 2 through 4 above are shown in Table 2.

TABLE 2

| | Example 2 | Example 3 | Example 4 |
|---|---|---|---|
| Standard Pressure (Torr) | 0.005 | 0.005 | 0.005 |
| Process Pressure (Torr) | 0.5 | 1.0 | 1.0 |
| Precursor | IGZO | IGZO | IGZO |
| | cocktail | cocktail | cocktail |
| Precursor Flow Rate (g/min) | 0.05 | 0.10 | 0.10 |
| Precursor Flow Time (s) | 1 | 1 | 3 |
| Reactive Gas | O₂ | O₂ plasma | O₂ plasma |
| Reactive Gas Flow Rate (sccm) | 100 | 200 | 200 |
| Reactive Gas Flow Time (s) | 1 | 5 | 5 |
| Process Temperature (° C.) | 100 | 200 | 200 |
| Purging Time (s) | 5 | 30 | 30 |
| Ar Gas Flow Rate (sccm) | 100 | 100 | 100 |

### Experimental Example

Experimental Example 1. Analysis of Physical Property of Liquid Three-Component Based Mixed Precursor Composition for Deposition of IGZO Thin Film

When a mixed molar ratio of indium:gallium:zinc in a liquid three-component based mixed precursor composition for deposition of an IGZO thin film was 1:1:1, a measurement method for obtaining physical property analysis, a device, and an analysis result are shown in Table 3.

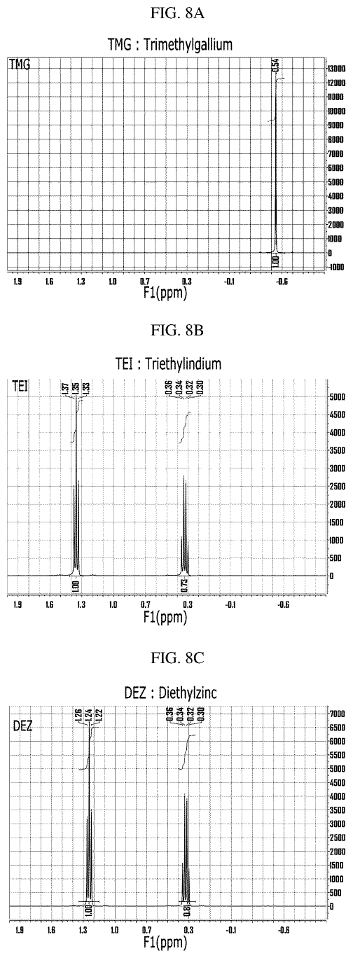

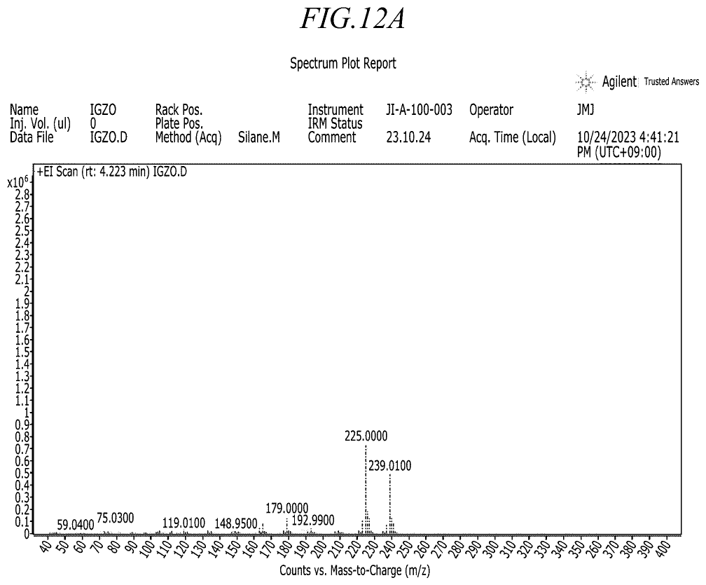

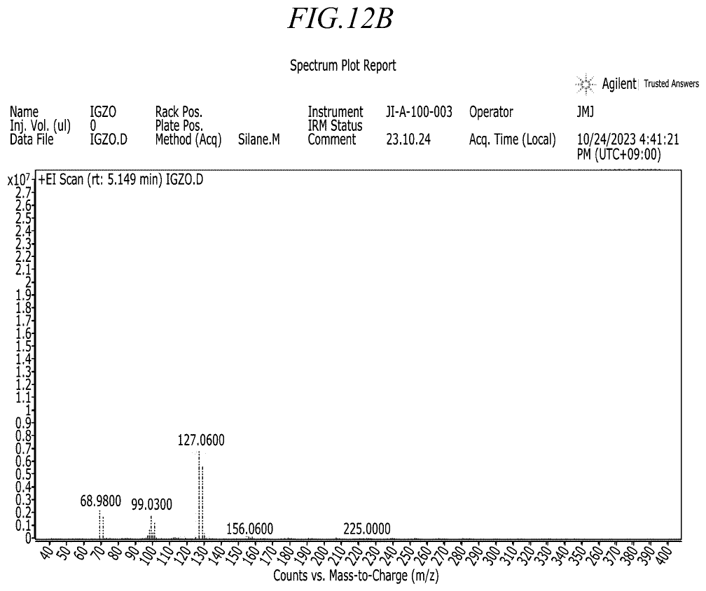

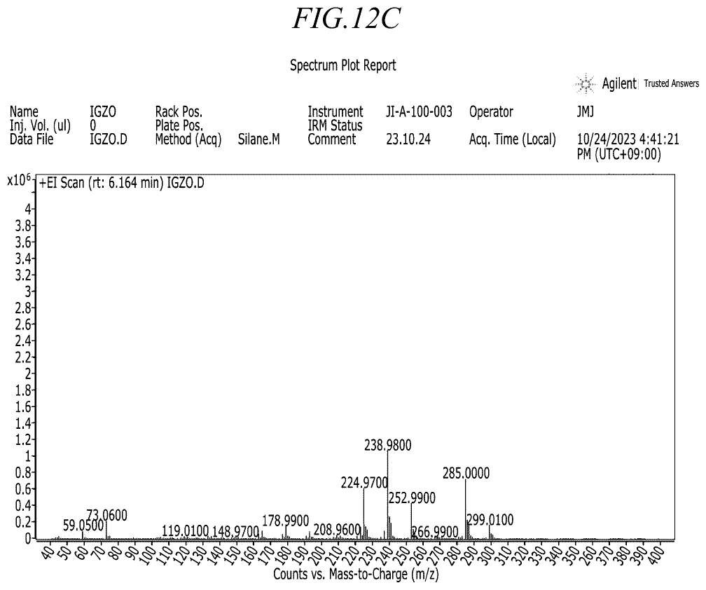

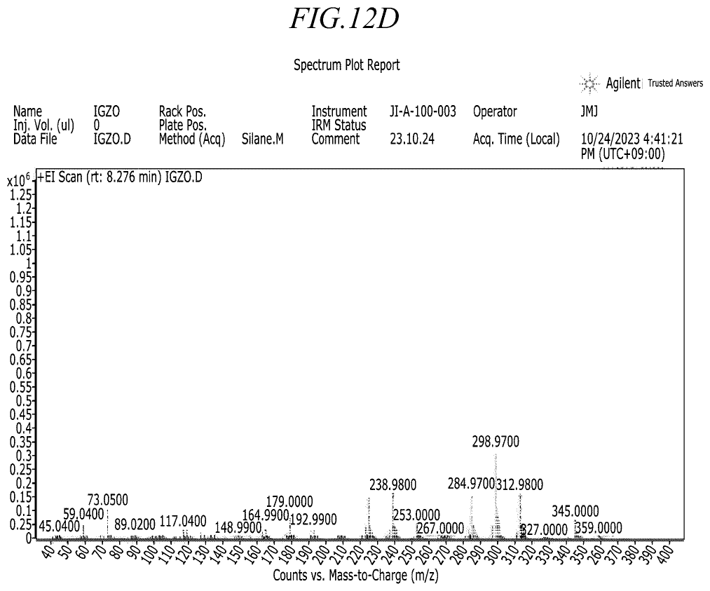

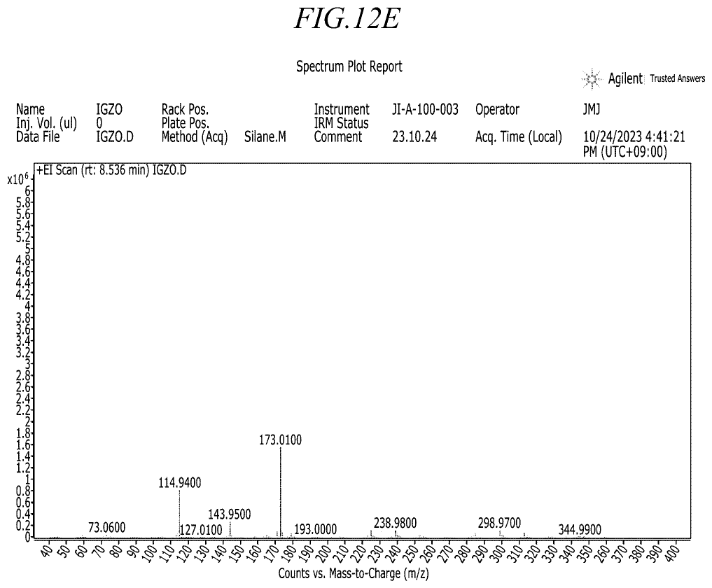

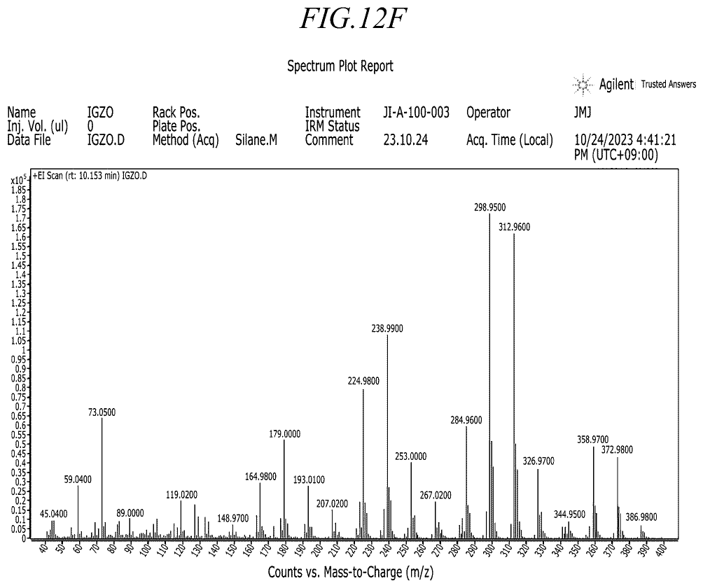

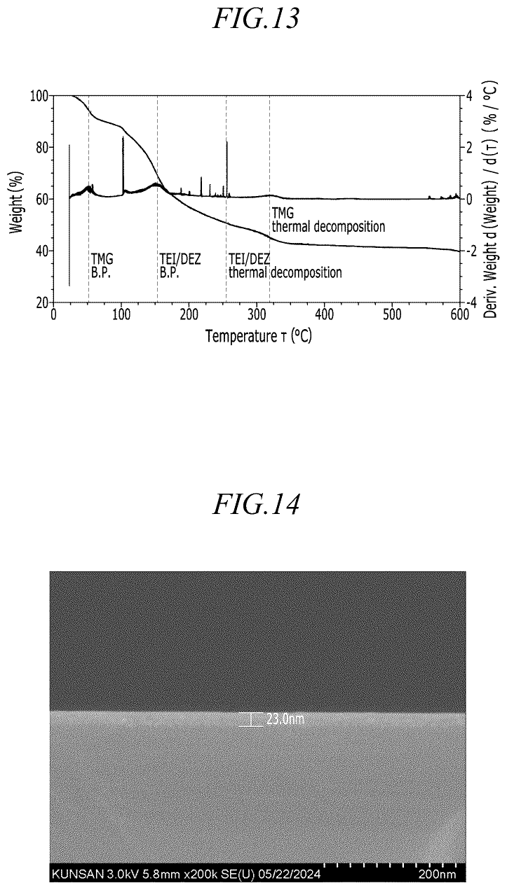

TABLE 3

| | Measurement | Device | |
|---|---|---|---|
| Category | Method | Name | Result |
| Molecular Formula | Calculation | — | IGZO cocktail |
| | | | source |
| Phase and Color | Measurement | Colorimeter | Colorless liquid |
| Molecular Weight | Calculation | — | 146.778 g/mol |
| Specific gravity | Measurement | Hydrometer | 1.27009944 |
| | | | @22° C. |
| Thermal | Measurement | TGA | 263° C. |
| Decomposition | | | |
| Temperature | | | |
| Viscosity | Measurement | Viscometer | 0.95 cP @22° C. |
| NMR | Measurement | NMR | FIGS. 8, 9 and 10 |
| GC-MS | Measurement | GC_MS | FIGS. 11 and 12 |
| TGA | Measurement | TGA | FIGS. 13 |

### Experimental Example 2. NMR Analysis of Liquid Three-Component Based Mixed Precursor Composition for Deposition of IGZO Thin Film

FIGS. 8A, 8B, 8C, 9A, 9B, 9C, 10A, 10B and 10C show an NMR analysis of the three-component based mixed precursor composition for deposition of an IGZO thin film manufactured in Example 1.

FIGS. 8A through 8C is a graph showing an NMR measurement of each source after synthesizing sources of gallium precursor, indium precursor, and zinc precursor for manufacturing a three-component based, mixed precursor composition for deposition of an IGZO thin film according to an embodiment of the present disclosure.

Referring to FIGS. 8A, 8B, and 8C, it can be confirmed through a peak shown in the graph that gallium precursor, indium precursor, and zinc precursor for manufacturing a three-component based mixed precursor composition for deposition of a thin film are respectively trimethylgallium, triethylindium, and diethylzinc.

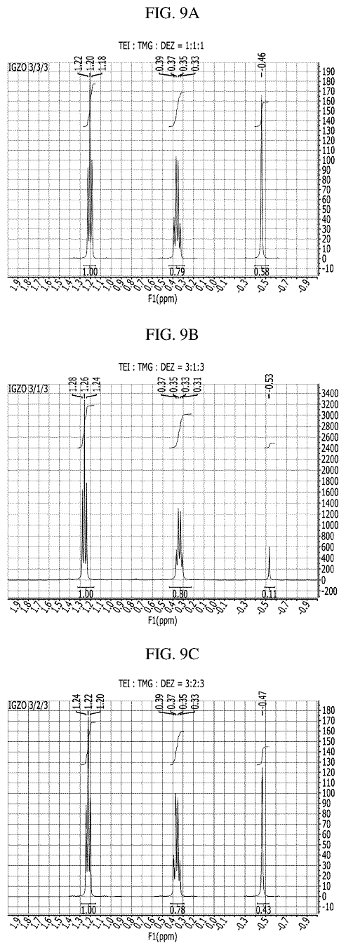

FIGS. 9A, 9B and 9C is a graph showing a result of a measured NMR of a composition after manufacturing a three-component based mixed precursor composition for deposition of an IGZO thin film according to an embodiment of the present disclosure;

Referring to FIGS. 9A, 9B and 9C, it is possible to control a composition ratio (a molar ratio) of triethylindium, trimethylgallium (TMG), and diethylzinc as 1:1:1 or 3:1:3. It was confirmed that a peak of gallium (Ga) decreases when a composition ratio (a molar ratio) of trimethylgallium decreases.

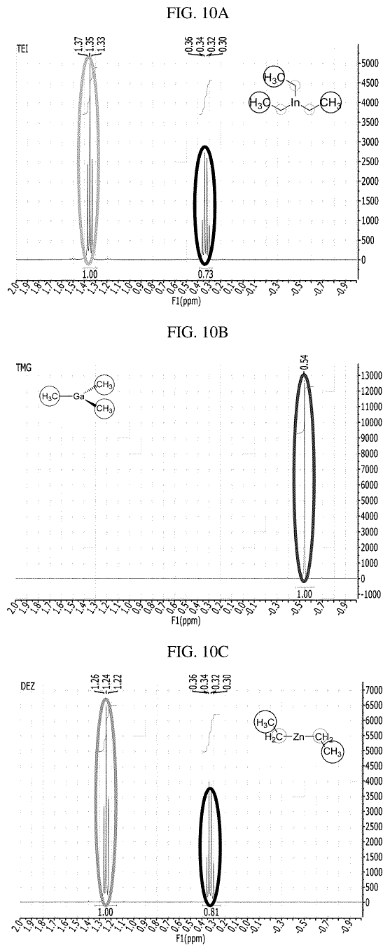

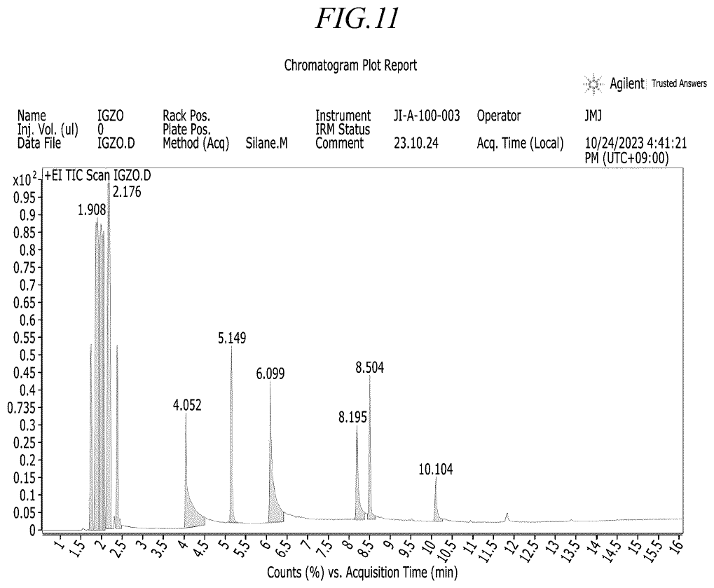

FIGS. 10A, 10B and 10C is an illustration showing an NMR analysis result of triethylindium, indium precursor according to an embodiment of the present disclosure.

Referring to FIGS. 10A, 10B and 10C, a peak corresponding to an ethyl group and a methyl group of triethylindium that is completely synthesized and refined, can be confirmed.

### Experimental Example 3. Analysis of Mass Spectrometry (GC/MS) of Liquid Three-Component Based Mixed Precursor Composition for Deposition of IGZO Thin Film

FIGS. 11 and 12A through 12F show a mass spectrometric (GC/MS) result of the three-component based mixed precursor composition for deposition of an IGZO thin film manufactured in Example 1.

FIG. 11 is an illustration of a mass spectrometric (GC/MS) result of a three-component based mixed precursor composition for deposition of an IGZO thin film according to an embodiment of the present disclosure.

FIG. 11 shows a signal intensity graph according to a timeline of a three-component based mixed precursor composition for deposition of an IGZO thin film. Referring to FIG. 11, it can be confirmed that a peak of a solvent for analysis is shown first and each component of a three-component based mixed precursor composition for deposition of an IGZO thin film is confirmed from a peak respectively at 4 min, 6 min and 8 min. FIG. 11 and FIGS. 12A through 12F are illustrations showing a gas chromatography-mass spectroscopy (GC/MS) result of each element in a three-component based mixed precursor composition for deposition of an IGZO thin film according to an embodiment of the present disclosure. Referring to FIGS. 11 and 12A through 12F, it can be confirmed that triethylindium, trimethylgallium (TMG), and diethylzinc are mixed in a three-component based mixed precursor composition for deposition of an IGZO thin film along with a molar ratio of each element. The above figures may be used as reference library data for gas chromatography-mass spectroscopy (GC/MS) of a three-component based, mixed precursor composition for deposition of an IGZO thin film.

### Experimental Example 4. TGA Analysis of Liquid Three-Component Based Mixed Precursor Composition for Deposition of IGZO Thin Film

FIG. 13 shows a TGA analysis result of the three-component based mixed precursor composition for deposition of an IGZO thin film manufactured in Example 1.

FIG. 13 is an illustration showing an analysis result by using thermogravimetric analysis (TGA) for measurement of thermal stability and decomposition temperature of liquid indium precursor, liquid gallium precursor, and/or liquid zinc precursor according to an embodiment of the present disclosure.

Referring to FIG. 13, it can be confirmed that masses of triethylindium, indium precursor according to an embodiment of the present disclosure, and diethylzinc, zinc precursor according to an embodiment of the present disclosure, decrease by about 50% at a temperature of about 250° C. The above shows excellence of thermal stability of triethylindium and diethylzinc of the present disclosure.

Referring to FIG. 13, a mass of trimethylgallium, gallium precursor according to an embodiment of the present disclosure, decreases by about 45% at a temperature of about 320° C. The above shows excellence of thermal stability of trimethylgallium of the present disclosure.

### Experimental Example 5. Side Reaction Analysis According to Molar Ratio of Liquid Three-Component Based Mixed Precursor Composition for Deposition of IGZO Thin Film

Table 4 shows whether a side reaction occurred according to a condition of a molar ratio of each element when a three-component based mixed precursor composition for deposition of an IGZO thin film is manufactured.

TABLE 4

| | In | Ga | Zn |
|---|---|---|---|
| 0.1 mol | X | X | X |
| 0.5 mol | X | X | X |
| 1.0 mol | X | X | X |
| 2.0 mol | X | X | X |
| 3.0 mol | X | X | X |
| 5.0 mol | X | X | X |
| 10.0 mol | X | X | X |

X: No side reaction occurred

Referring to Table 4, an undesired side reaction does not occur when 0.1 mol, 0.5 mol, 1.0 mol, 2.0 mol, 3.0 mol, 5.0 mol, or 10.0 mol of indium, gallium, and zinc are synthesized at a molar ratio of 1:1:1, respectively.

### Experimental Example 6. Analysis of Side Reaction Occurrence Based on Mixing Condition of Liquid Three-Component Based Mixed Precursor Composition for Deposition of IGZO Thin Film

Table 5 shows whether a side reaction or a floating matter occurs, change of color, and change of temperature according to a mixing condition (RPM and mixing time) for manufacturing a three-component based mixed precursor composition for deposition of an IGZO thin film.

TABLE 5

RPM

| MIN | 100 | 300 | 600 | 800 | 1,000 |
|---|---|---|---|---|---|
| 10 | X | X | X | X | X |
| 20 | X | X | X | X | X |
| 30 | X | X | X | X | X |
| 60 | X | X | X | X | X |

X: No side reaction and floating matter occurrence, no color change and no temperature change

Referring to Table 5, mixing indium precursor, gallium precursor, and zinc precursor at 100 RPM, 300 RPM, 600 RPM, 800 RPM, and 1,000 RPM for 10 mins, 20 mins, 30 mins, and 60 mins did not show occurrence of an undesired side reaction and a floating matter, change of color and change of temperature.

### Experimental Example 7. Evaluation of Physical Property of Thin Film

A thin film was manufactured using a three-component based mixed precursor composition for deposition of an IGZO thin film, and a physical property of the thin film was evaluated.

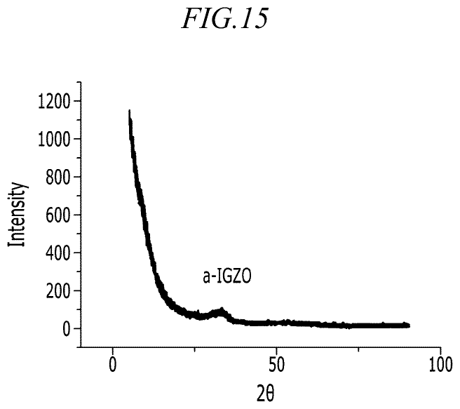

FIG. 14 is an SEM image of a cross-sectional view of an IGZO thin film formed through atomic layer deposition according to an embodiment of the present disclosure. FIG. 15 is graph showing an XRD result of an IGZO thin film formed through atomic layer deposition according to an embodiment of the present disclosure.

Referring to FIGS. 14 and 15, when a liquid three-component based mixed precursor composition for deposition of an IGZO thin film was provided at a room temperature by using liquid delivery system (LDS) and vaporized with a vaporizer to form a thin film, it could be confirmed that the formed thin film had smooth surface, excellent film quality and an amorphous IGZO thin film structure that is similar to a thin film deposited through PVD. A thin film formed through atomic layer deposition using a precursor composition including liquid indium precursor, liquid gallium precursor, and liquid zinc precursor for deposition of a thin film according to an embodiment of the present disclosure shows an amorphous phase so that it is possible to show very excellent electron mobility and improve electrical property of the thin film.

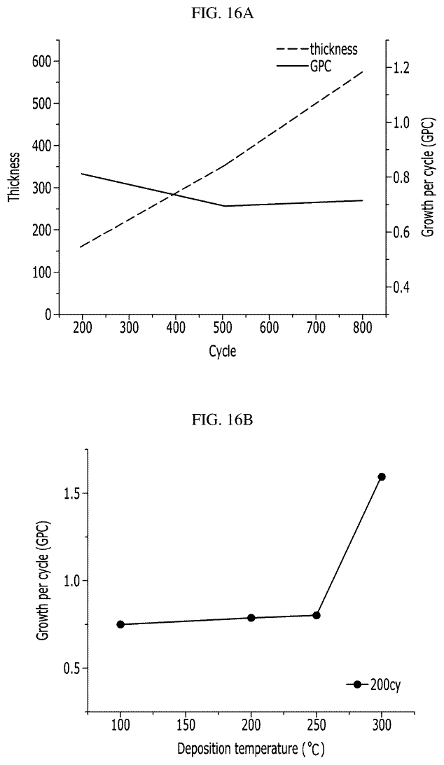

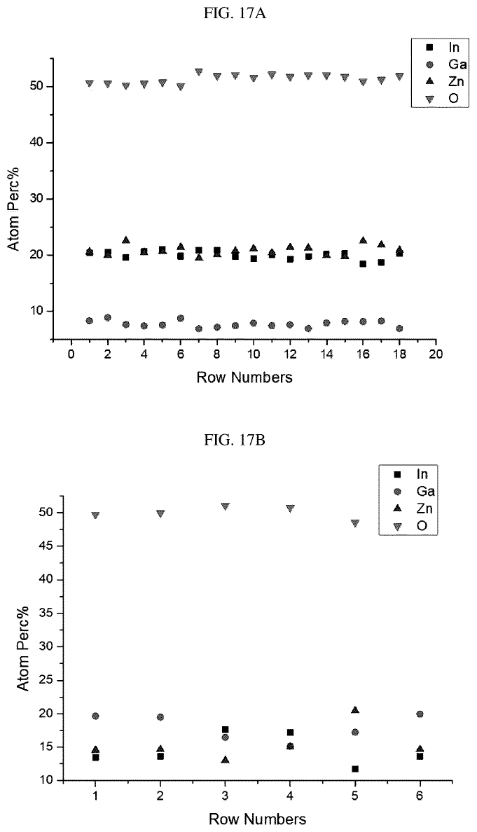

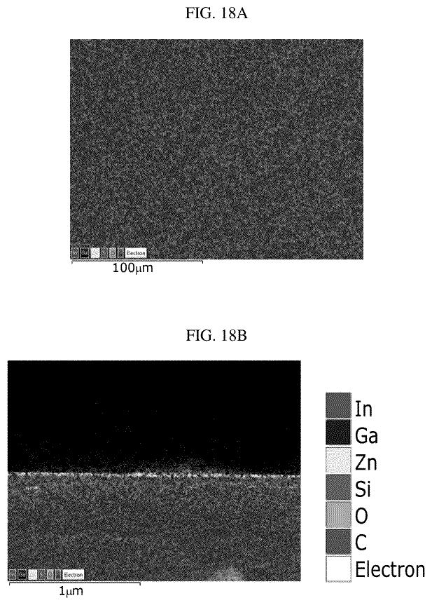

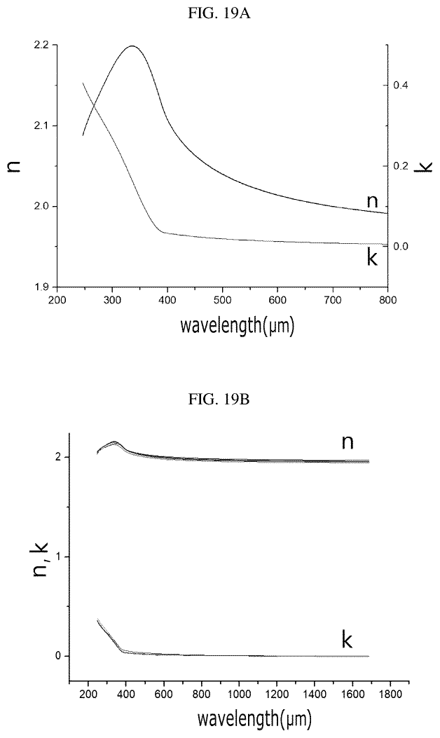

FIG. 16A is an illustration showing a growth per cycle (GPC) and a thickness measurement result with an ellipsometer according to the number of deposition of a thin film formed through atomic layer deposition according to an embodiment. FIG. 16B is an illustration showing growth per cycle (GPC) according to a deposition temperature of a thin film formed through atomic layer deposition according to an embodiment of the present disclosure.

Referring to FIG. 16A, it can be confirmed with the growth per cycle (GPC) according to the number of atomic layer deposition according to an embodiment that as a cycle and thickness graph is positively inclined, a thickness of a substrate uniformly increases with an increase in a cycle. Accordingly, a cycle may be selected for deposition of a desired thickness necessary for a device and a thickness may be suitably controlled by adjusting a cycle.

In addition, considering that growth of a thin film may be slightly faster due to a phenomenon of a high growth per cycle (GPC) in an early stage of deposition, the number of deposition cycles may be suitably adjusted according to a deposition thickness.

Although the present disclosure is not limited thereto, a thickness changes according to the number of atomic layer deposition according to an embodiment follows growth per cycle (GPC), a thickness of about 0.8 Å is deposited per cycle in an early stage of deposition, and a thickness of about 0.7 Å is deposited per cycle in a later stage (500 cycles or more) of deposition. Accordingly, as a deposition cycle is adjusted, a thickness is suitably controlled so that a desired thickness may be deposited.

In FIG. 16B, an ALD window was confirmed by measuring a growth rate according to a different temperature for an atomic layer deposition (ALD) process. FIG. 16B shows an ALD window having a constant growth rate when a deposition temperature is between 100° C. and 250° C. As a thickness of about 0.7 Å of a thin film is deposited per cycle within the above deposition temperature range, an ALD deposition of a thin film is well performed within the range. However, when a deposition temperature is over 300° C., a growth rate drastically increases. This shows that an IGZO thin film may not be deposited using a three-component based mixed precursor composition of deposition of an IGZO thin film because the three-component based mixed precursor composition is thermally decomposed. Therefore, although the present disclosure is not limited thereto, a deposition temperature of atomic layer deposition according to an embodiment of the present disclosure may be suitably between 100° C. and 300° C., and suitably between 100° C. and 250° C.

FIGS. 17A and 17B are illustrations of a composition ratio of a thin film by using X-ray photoelectron spectroscopy (XPS) spectrum of a thin film formed through atomic layer deposition using a liquid three-component based mixed precursor composition for deposition of an IGZO thin film according to an embodiment of the present disclosure.

FIGS. 17A and 17B show an atomic composition ratio in a thin film when a molar ratio of indium:gallium:zinc in the precursor composition for deposition of a thin film is, respectively, 3:1.1:3 and 3:3:3, respectively. Referring to FIG. 17A showing an atomic composition ratio in a thin film formed by mixing with a molar ratio of indium:gallium:zinc in the precursor composition for deposition of a thin film as 3:1.1:3, atomic percentages (at %) of indium and zinc on a thin film are shown to be about between 15 at % and 25 at %, and an atomic percentage (at %) of gallium on a thin film is shown to be 10 at % or less, which is the lowest and much different from atomic percentages of other atoms. However, referring to FIG. 17B showing an atomic composition ratio in a thin film formed by mixing with a molar ratio of indium:gallium:zinc in the precursor composition for deposition of a thin film as 3:3:3, it can be confirmed that each of atomic percentages of indium, gallium, and zinc on a thin film is uniformly spread between about 10 at % and 20 at %.

When a thin film is formed through a single process with a three-component based mixed precursor composition for deposition of an IGZO thin film, a ratio of actually deposited atom may be different due to difference in reactivity of precursor of each atom. Particularly, reactivity of gallium is relatively lower than that of indium or zinc. Therefore, molar concentration of gallium, which has low reactivity, may be adjusted to have a value greater than a molar concentration of indium and zinc for controlling a ratio of each element included in a thin film. In addition, a process condition during formation of a thin film may be controlled to suitably control a ratio of an atom included in a thin film.

FIGS. 18A and 18B are respectively a surface mapping image and a cross-sectional mapping image of atoms through an SEM_EDS analysis of a thin film formed through atomic layer deposition according to an embodiment of the present disclosure, and each atom in a thin film is distinguished by color. Referring to FIG. 18, it can be confirmed that an atom in an IGZO thin film is uniformly distributed.

FIGS. 19A and 19B is an illustration showing a refractive index and an absorption coefficient of a thin film formed through atomic layer deposition according to an embodiment of the present disclosure. Referring to FIGS. 19A and B, it can be confirmed that an IGZO thin film within a wavelength range between 400 nm and 1,600 nm has a refractive index n of about 2 and an absorption coefficient k converges to 0. Particularly, a refractive index n with a wavelength of 632 nm within the visible light range (400 to 800 nm) is 2.04, and an absorption coefficient k is close to 0.

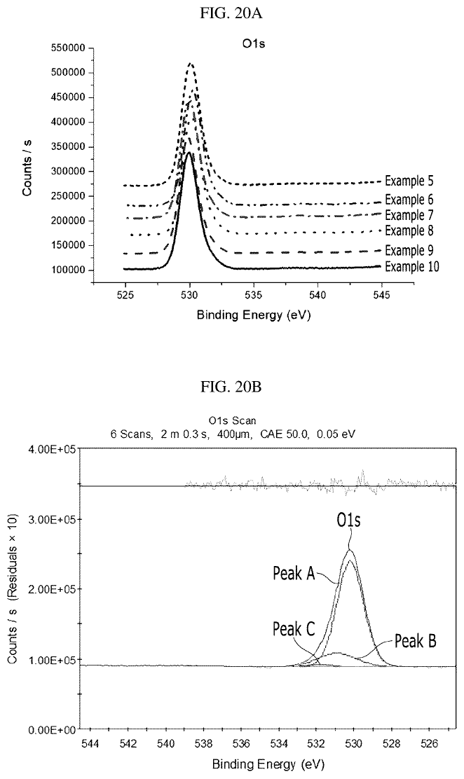

FIG. 20A is an illustration of an O1s peak for a thin film using X-ray photoelectron spectroscopy (XPS) spectrum of a thin film formed through atomic layer deposition according to an embodiment of the present disclosure. Referring to FIG. 20A, it can be confirmed that a peak at bond energy of about 532 eV in Examples 5 through 10, where conditions of an oxygen flow rate and plasma power are different, is slightly shifted. Table 6 shows conditions of an argon supply amount, an oxygen supply amount, a supply time, and plasma power in Examples 5 through 10 shown in FIG. 20A.

TABLE 6

| | First Period of Supplying | | Second Period of Supplying O2 | | |
|---|---|---|---|---|---|
| | O2 Source Material | | Source Material | | |
| | Argon Supply Amount (sccm): 100 sccm | | | | |
| | Oxygen Supply | Supply | Plasma | Oxygen Supply | Supply |
| Example | Amount (sccm) | Time (s) | Supply (W) | Amount (sccm) | Time (s) |
| Example 5 | 50 | 3 | 50 | 50 | 3 |
| Example 6 | 100 | 3 | 50 | 100 | 3 |
| Example 7 | 150 | 3 | 100 | 150 | 3 |
| Example 8 | 200 | 3 | 200 | 200 | 3 |
| Example 9 | 200 | 3 | 250 | 200 | 3 |
| Example 10 | 200 | 3 | 300 | 200 | 3 |

FIG. 20B is a graph showing a peak after deconvolution of an O1s peak into three peaks. Referring to FIG. 20B, an O1s peak is detected at 532 eV, and a detection position of a peak is shifted depending on a binding with another atom. Table 7 shows each of a peak, a binding and an integral size of a peak.

TABLE 7

| | | Integral |
|---|---|---|
| | | Size of |
| Peak | Binding with Atom | Peak |
| Peak A | Metallic bonding [M—O, Metal-Oxide] | 81.66% |
| Peak B | Oxygen vacancy [O—Ov, Oxide-Oxygen vacancy] | 16.22% |
| Peak C | Hydrogen bonding [O—H, Oxide-Hydrogen] | 2.12% |

Referring to Table 7, Peak A shows a metal-oxide bond with an integral size of peak of 81.66%, Peak B is an oxygen vacancy bond with an integral size of peak of 16.22%, and Peak C is an oxygen-hydrogen bond with an integral size of peak of 2.12%. Accordingly, it can be confirmed that the metal-oxide bond exists the most in the IGZO thin film according to an embodiment of the present disclosure.

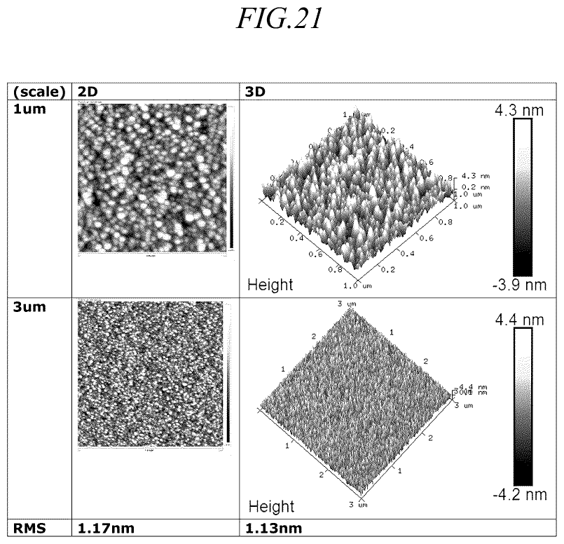

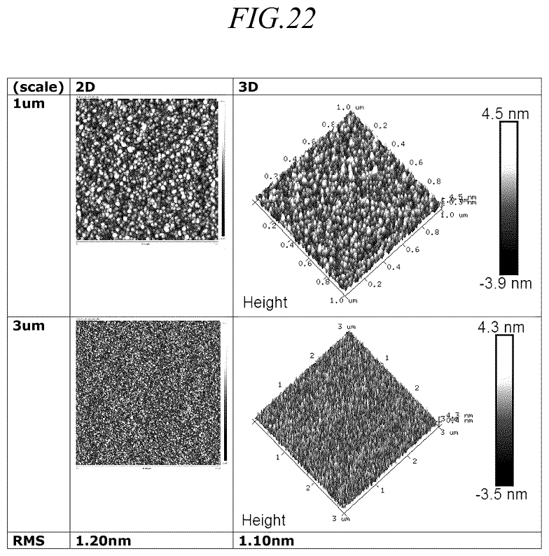

FIGS. 21 and 22 are atomic force microscopy (AFM) illustrations showing growth behavior and root-mean-square surface roughness of an IGZO thin film according to an embodiment of the present disclosure through a three-dimensional granular morphology and a two-dimensional morphology.

FIGS. 21 and 22 show root-mean-square surface roughness (RMS) of an IGZO thin film according to an embodiment of the present disclosure in two-dimension and three-dimension by using AFM. Referring to FIG. 21, when a thickness of a thin film is 45 nm, the RMSs are 1.17 nm and 1.13 nm in two-dimension and three-dimension, respectively. Referring to FIG. 22, when a thickness of a thin film is 45 nm, the RMSs are 1.20 nm and 1.10 nm in two-dimension and three-dimension, respectively. Accordingly, it can be confirmed that when a thickness of a thin film is 45 nm, a single layer continuous IGZO thin film is formed to maintain even surface roughness and its surface roughness is maintained below 1.20 nm.

### Experimental Example 8. Evaluation of Thin Film Transistor Property

By using a three-component based mixed precursor composition for deposition of an IGZO thin film, a thin film was manufactured, and a thin film transistor including the manufactured thin film as an active layer ACT was manufactured. An electronic device ECD1 through ECD7 including the thin film transistor may be provided.

FIG. 5A is a schematic cross-sectional view of a thin film transistor including an IGZO thin film formed by using a three-component based mixed precursor composition for deposition of an IGZO thin film according to an embodiment of the present disclosure, and FIG. 5B is a schematic front view of the thin film transistor.

Referring to FIG. 5A, a highly doped Si substrate GS with an SiO₂ buffer layer BF formed with a thickness of 100 nm on the substrate is used, an active layer ACT is formed through deposition of an IGZO thin film on the SiO₂ buffer layer BF, and a thin film transistor including a source electrode S and a drain electrode D positioned to face each other on the active layer ACT is manufactured.

Referring to FIG. 5B, a width W and a length L of the thin film transistor were 800 μm and 40 μm, respectively.

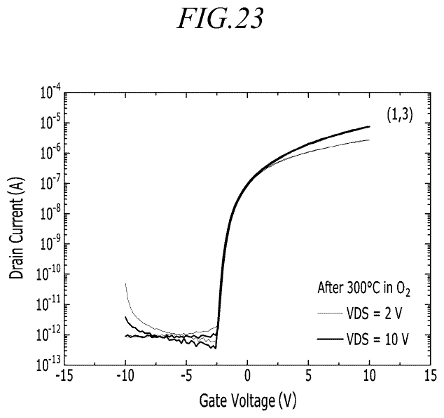

FIG. 23 is a transfer curve showing reliability evaluation result of an IGZO thin film according to an embodiment of the present disclosure.

Referring to FIG. 23, the IGZO thin film transistor is shown to have very excellent stability and durability as a change in threshold voltage due to light-voltage or voltage stress is less than 1V. Accordingly, by using a liquid three-component based mixed precursor composition for deposition of an IGZO thin film according to an embodiment of the present disclosure, a process time may be reduced while maintaining a thin film transistor property. By using a three-component based mixed precursor composition for deposition of an IGZO thin film according to an embodiment of the present disclosure, a thin film may be manufactured and a thin film transistor including the manufactured thin film as an active layer ACT may be used as a switching device or a driving device in a pixel of a display, i.e. an active matrix display such as a liquid crystal display or organic light-emitting display, and may be applicable to a flat-panel display such as active matrix liquid crystal display (AMLCD) and active matrix organic light emitting diode (AMOLED) of a new generation for providing an ultra-high definition (UHD) image. Other than the above, it may be applicable to other electronic device such as a memory device and a logic device for various purposes.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims.

Therefore, the technical scope of the present disclosure should be interpreted by the scope of the claims, instead of being restricted the disclosed description in Detailed Description.

What is claimed is:

1. A precursor composition for deposition of a thin film, comprising:
liquid indium precursor;
liquid gallium precursor; and
liquid zinc precursor.

2. The precursor composition for deposition of the thin film of claim 1, wherein a molar ratio of indium:gallium:zinc in the precursor composition for deposition of the thin film is 0.1 to 10:0.1 to 10:0.1 to 10.

3. The precursor composition for deposition of the thin film of claim 1, wherein the liquid indium precursor is at least one species selected from triethylindium, triisopropylindium, and tri (tert-butyl) indium.

4. The precursor composition for deposition of the thin film of claim 1, wherein the precursor composition for deposition of the thin film does not include a solvent.

5. The precursor composition for deposition of the thin film of claim 1, wherein all of the liquid indium precursor, the liquid gallium precursor, and the liquid zinc precursor are alkyl-based precursor.

6. A manufacturing method of a thin film, comprising:
preparing a precursor composition for deposition of the thin film by mixing liquid indium precursor, liquid gallium precursor, and liquid zinc precursor; and
forming the thin film on a substrate by using the precursor composition.

7. The manufacturing method of the thin film of claim 6, wherein indium, gallium and zinc in the precursor composition for deposition of the thin film are mixed with a molar ratio of 0.1 to 10:0.1 to 10:0.1 to 10.

8. The manufacturing method of the thin film of claim 6, wherein the liquid indium precursor is at least one species selected from triethylindium, tripropylindium, and tri (tert-butyl) indium.

9. The manufacturing method of the thin film of claim 6, wherein the precursor composition for deposition of the thin film does not involve a solvent.

10. The manufacturing method of the thin film of claim 6, wherein the forming of the thin film is performed through atomic layer deposition (ALD) or chemical vapor deposition (CVD) by using the precursor composition for deposition of the thin film.

11. The manufacturing method of the thin film of claim 6, wherein a temperature forming the thin film is between 100° C. and 300° C.

12. The manufacturing method of the thin film of claim 6, further comprising:
vaporizing the precursor composition using a vaporizer before forming the thin film.

13. The manufacturing method of the thin film of claim 6, further comprising:
first purging a chamber using inert gas after forming the thin film.

14. The manufacturing method of the thin film of claim 13, further comprising:
oxidizing the thin film by using reactive gas after the first purging.

15. The manufacturing method of the thin film of claim 14, wherein a flow rate of the reactive gas is between 50 sccm and 500 sccm, and
wherein a supply time of the reactive gas is between 0.1 seconds and 60 seconds.

16. The manufacturing method of the thin film of claim 14, further comprising:
second purging the chamber using inert gas after the oxidizing the thin film.

17. An electronic device comprising:
a thin film formed by using a precursor composition comprising liquid indium precursor, liquid gallium precursor, and liquid zinc precursor,
wherein the thin film is a single amorphous layer including indium, gallium and zinc.

18. The electronic device of claim 17, wherein the electronic device is one of a plane panel display, a curved display, a television, a billboard, a computer monitor, a medical monitor, a head mounted display (HMD), an indoor or outdoor lighting or light for signal, a wearable device, a foldable device, a rollable device, a bendable device, a flexible device, a curved device, an electronic notebook, an electronic book, a portable multimedia player (PMP), a personal digital assistant (PDA), a laser printer, a telephone, a cellphone, a tablet, a portable terminal, a notebook, a laptop, a digital camera, a viewfinder, a camcorder, a 3D display, a virtual reality or augmented reality display, a video wall containing multiple displays tiled together, a vehicle, an outdoor display device, a theater or stadium screen, and a signboard.

19. The electronic device of claim 17, wherein a ratio of indium in the thin film is more than or equal to 10 wt %.

20. The electronic device of claim 17, wherein the thin film has a refractive index of between 1.5 and 2.5 at 630 nm.
